(19) United States
(12) Patent Application Publication
(10) Pub. No.: US 2026/0304949 A1
(43) Pub. Date: Oct. 1, 2026

(54) INDIVIDUALIZED TUB GATES WITH CHANNEL AND GATE HEIGHT DIFFERENTIALS

(71) Applicant: Intel Corporation, Santa Clara, CA (US)

(72) Inventors: Dan Lavric, Portland, OR (US); Glenn Glass, Portland, OR (US); Leonard Guler, Hillsboro, OR (US)

(73) Assignee: Intel Corporation, Santa Clara, CA (US)

(21) Appl. No.: 19/092,827

(22) Filed: Mar. 27, 2025

(51) Int. Cl. H10D 84/85; H10D 84/01

(52) U.S. Cl. CPC H10D 84/856; H10D 84/0167; H10D 84/851

(57) ABSTRACT

Integrated circuit (IC) devices having gate-all-around (GAA) transistors. An IC device may include adjacent GAA transistors separated by a dielectric wall and having gate structures with different heights and with gate dielectric layers on nanoribbon channels and on the dielectric wall. Nanoribbon stacks in the adjacent transistors may have different heights, compositions, and thicknesses. The gate dielectric layers in the adjacent transistors may have different thicknesses or material compositions. Gate metal layers of the adjacent transistors may have different thicknesses or material compositions. The dielectric wall between gate structures may enable independent processing of the transistors gates by dividing the nanoribbon channels into separate gate tubs.

### BACKGROUND

As gate-all-around (GAA) transistors are continuously scaled, gate geometries shrink, and less space is available for gate material patterning. Increases in patterning precisions may be required to improve transistor performance, reduce process variabilities, and/or prevent reliability issues. For example, the deposition or removal of different (e.g., optimized) materials, or the formation of differently sized (e.g., optimized metal gate) structures, in adjacent (e.g., complementary) transistors may be infeasible (or unduly expensive) using conventional GAA gate patterning schemes.

New techniques, structures, and materials are needed to improve metal gates in complementary GAA transistors.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements, e.g., with the same or similar functionality. The disclosure will be described with additional specificity and detail through use of the accompanying drawings:

FIGS. 1A, 1B, and 1C illustrate cross-sectional profile and plan views of an integrated circuit (IC) device with transistor structures having different gate structures separated by a slim dielectric wall, in accordance with some embodiments;

FIGS. 2A, 2B, and 2C illustrate cross-sectional profile views of an IC device with transistor structures having gate structures with different gate heights and separated by a dielectric wall, in accordance with some embodiments;

FIG. 3 is a flow chart of methods for forming nanoribbon channel and gate structures with different heights and compositions over stacks of nanoribbons, in accordance with some embodiments;

FIGS. 4A, 4B, 4C, 4D, 4E, 4F, 4G, and 4H illustrate isometric and plan views of an IC device having gate structures of different heights and compositions over nanoribbons of different heights and compositions, at various stages of manufacture, in accordance with some embodiments;

FIG. 5 illustrates a diagram of an example data server machine employing an IC device having a dielectric wall separating channel and gate structures with different heights; and

FIG. 6 is a block diagram of an example computing device, in accordance with some embodiments.

### DETAILED DESCRIPTION

In the following detailed description, reference is made to the accompanying drawings that show, by way of illustration, specific embodiments in which the claimed subject matter may be practiced. These embodiments are described in sufficient detail to enable those skilled in the art to practice the subject matter. The various embodiments, although different, are not necessarily mutually exclusive. For example, a particular feature, structure, or characteristic described herein, in connection with one embodiment, may be implemented within other embodiments without departing from the spirit and scope of the claimed subject matter.

References within this specification to “one embodiment” or “an embodiment” mean that a particular feature, structure, or characteristic described in connection with the embodiment is included in at least one implementation encompassed within the present description. Therefore, the use of the phrase “one embodiment” or “in an embodiment” does not necessarily refer to the same embodiment. In addition, the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled.

The terms “over,” “to,” “between,” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

The terms “coupled” and “connected,” along with their derivatives, may be used herein to describe structural relationships between components. These terms are not intended as synonyms for each other. Rather, in particular embodiments, “connected” may be used to indicate that two or more elements are in direct physical or electrical contact with each other. “Coupled” may be used to indicate that two or more elements are in either direct or indirect (with other intervening elements between them) physical or electrical contact with each other, and/or that the two or more elements co-operate or interact with each other (e.g., as in a cause-and-effect relationship, an electrical relationship, a functional relationship, etc.).

The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The vertical orientation is in the z-direction and recitations of “top,” “bottom,” “above,” and “below” refer to relative positions in the z-dimension with the usual meaning. However, embodiments are not necessarily limited to the orientations or configurations illustrated in the figure.

The terms “substantially,” “close,” “approximately,” “near,” and “about,” generally refer to being within +/−10% of a target value (unless specifically specified). Unless otherwise specified in the specific context of use, the term “predominantly” means more than 50%, or more than half. For example, a composition that is predominantly a first constituent means more than half of the composition is the first constituent. The term “primarily” means the most, or greatest, part. For example, a composition that is primarily a first constituent means the composition has more of the first constituent than any other constituent. A composition that is primarily first and second constituents means the composition has more of the first and second constituents than any other constituent.

Unless otherwise specified the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional,” “profile,” and “plan” correspond to orthogonal planes within a cartesian coordinate system. Thus, cross-sectional and profile views are taken in the x-z and y-z planes, and plan views are taken in the x-y plane. Typically, profile views in the x-z plane are cross-sectional views. Where appropriate, drawings are labeled with axes to indicate the orientation of the figure.

Techniques, structures, and materials are disclosed to improve integrated circuit (IC) devices having gate-all-around (GAA) metal-oxide-semiconductor (MOS) field-effect transistors (FETs).

Dielectric walls may separate adjacent nanoribbon stacks into individual processing compartments (“tubs”), thereby enabling independent fabrication of nanoribbon stacks, gate dielectric stacks, and metal gates in adjacent GAA FETs. Instead of every channel material layer (e.g., nanoribbon) stack in a shared gate trench undergoing the same processing, each material layer stack may have its own gate tub and receive specifically tailored processing. The dielectric walls may be formed by making many etches through long dummy gates in gate trenches and by filling the etched openings with dielectric, forming many isolations between many nanoribbon stacks. Openings may be patterned through a hardmask layer deposited over the walls and material layer stacks, and dummy gate material may be removed through the openings, evacuating selected tubs between the dielectric walls.

The mask openings may be made to evacuate groups of tubs selected for a particular processing operation. For example, the gate tubs for all (or at least many) material layer stacks to employ a group of first (e.g., silicon) material layers or to receive a certain gate dielectric material or thickness may be evacuated together and then receive the further processing concurrently. The hardmask layer may be removed following the completion of the particular processing operation, a new hardmask layer may be deposited, and new openings may be patterned to evacuate a new group of tubs for a next processing operation. For example, the new group of tubs may employ a group of second (e.g., silicon germanium) material layers or receive a second gate dielectric material or thickness. The dielectric walls may be retained after gate formation as electrical isolation between adjacent metal gate electrodes.

The tailored processing enabled by the gate tubs may be used to provide multiple channel and gate variants, for example, having nanoribbon channels of different compositions and heights and gate stacks with different threshold voltages V_{T} and corresponding leakages and switching speeds. Transistors of complementary conductivity types may have nanoribbon channels using optimized materials for that type, and the different (e.g., optimized) material layers may have different (e.g., staggered) heights in adjacent channel material layer stacks. Transistors may have metal gates with different heights, e.g., to minimize parasitic capacitances. The different gate heights may be achieved by selectively recessing metal gates in selected gate tubs.

Also as enabled by the separated gate tubs and the independent processing, an IC device may have multiple gate variants for each of multiple complementary conductivity types. For example, an IC device may have a spread of four or more threshold voltages V_{T} among NMOS FETs and a spread of four or more threshold voltages V_{T} among PMOS FETs. In many embodiments, adjacent transistors have different thicknesses of gate dielectric layers directly on channel nanoribbons. In many embodiments, adjacent transistors have different thicknesses of gate dielectric layers (e.g., high-permittivity or “high-k” layers) over the layers directly on the nanoribbons. For example, gate dielectric layer thicknesses may differ by 2 angstroms (or as much as 5 angstroms) in adjacent transistors. In many embodiments, adjacent transistors have gate dielectric layers with different high-k materials. In some embodiments, adjacent transistors have gate dielectric layers with different material compositions (e.g., elemental ratios) of the same high-k materials.

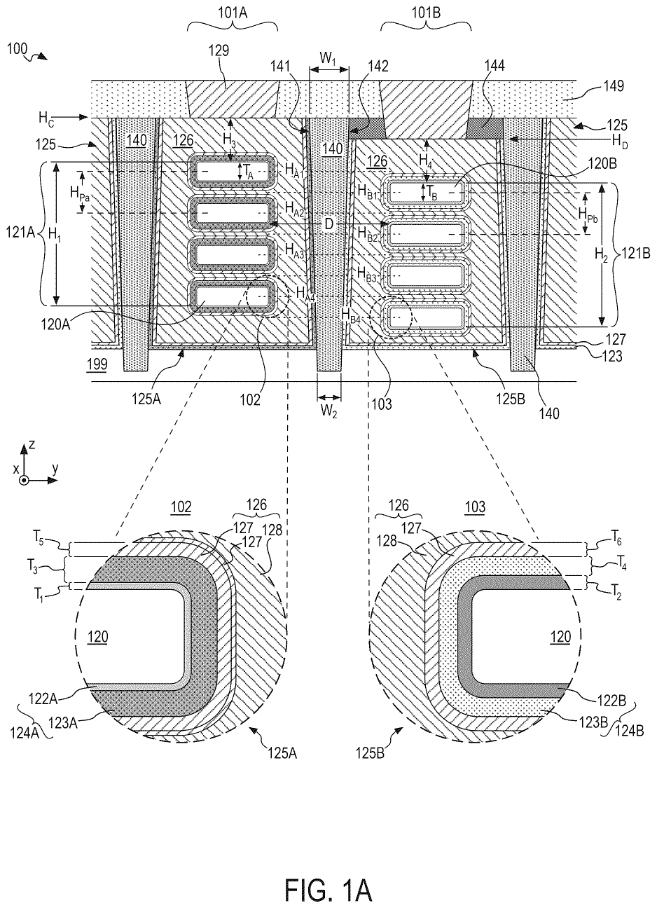

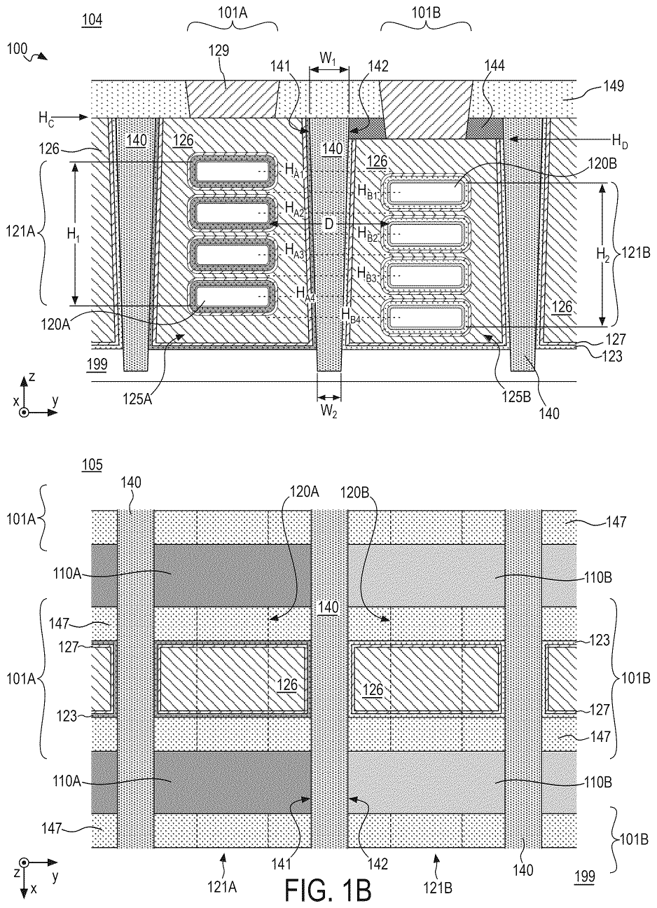

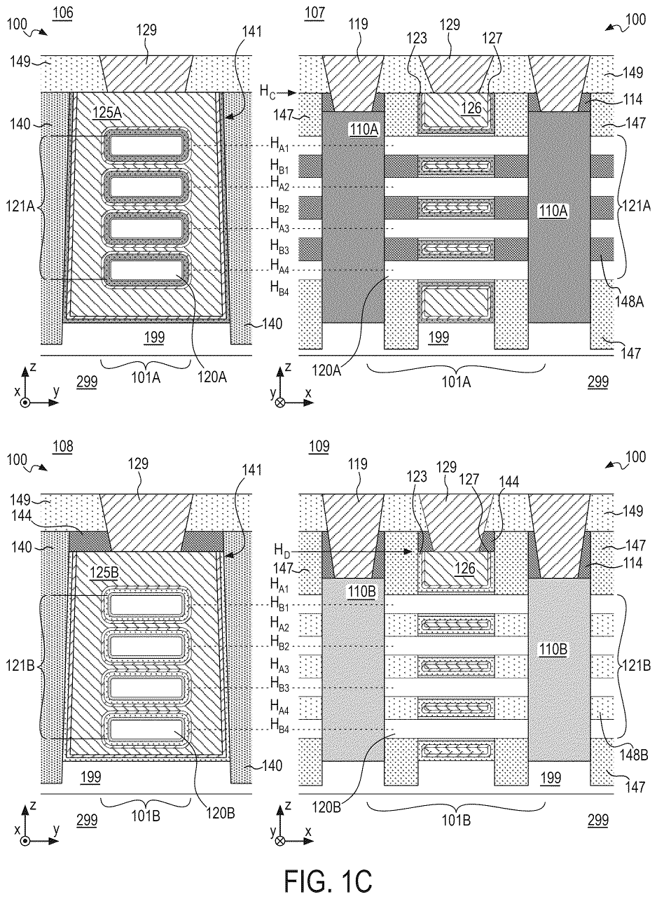

FIGS. 1A, 1B, and 1C illustrate cross-sectional profile and plan views of an IC device 100 with transistor structures 101A, 101B having different gate structures 125A, 125B separated by a slim dielectric wall 140, in accordance with some embodiments. Gate structures 125A, 125B may have different gate heights (or positions). Transistor structures 101A, 101B are GAA FET structures 101 having channel regions in stacks 121A, 121B of nanoribbons 120 (e.g., nanoribbons 120A, 120B) through gate structures 125A, 125B, respectively. Nanoribbons 120 in different stacks 121A, 121B may be at different heights (e.g., heights staggered, interleaved, etc., relative to the other stack 121, either stack 121A or 121B) and may have different compositions. FIG. 1A shows a y-z viewing plane transversely through nanoribbons 120 in multiple, adjacent stacks 121A, 121B and transistor structures 101. FIG. 1A includes multiple (e.g., enlarged) views 102, 103 of gate structures 125A, 125B with different heights H_{C}, H_{D} on and around nanoribbons 120 at different heights H_{A}, H_{B} (e.g., heights H_{A1}, H_{A2}, H_{A3}, H_{A4} above heights H_{B1}, H_{B2}, H_{B3}, H_{B4}, respectively). FIG. 1B shows a y-z profile view 104 and an x-y plan view 105, both through dielectric walls 140 between and in contact with gate structures 125 and source or drain bodies 110 (e.g., bodies 110A, 110B) in transistor structures 101A, 101B. FIG. 1C illustrates cross-sectional profile views 106, 107, 108, 109 of device 100 through gate structures 125A, 125B with (and nanoribbons 120 at) different heights in transistor structures 101A, 101B.

FIG. 1A shows device 100 including isolation wall 140 between and separating first and second gate structures 125A, 125B in transistor structures 101A, 101B, respectively. Gate structures 125A, 125B include at least gate electrodes 126 and gate dielectric layers 123. Gate structures 125A, 125B may have different sizes or positions such that upper surfaces of structures 125A, 125B are at different heights H_{C}, H_{D}. As in the exemplary embodiment shown in FIG. 1A, one of structures 125A, 125B may have a reduced or lower height H_{C} or H_{D} and, e.g., correspondingly reduced parasitic capacitances. In some embodiments, as shown in FIG. 1A, a first (vertical position or) height H_{C} of a first upper surface of the first gate structure 125A is greater than (e.g., above) a second (vertical position or) height H_{D} of a second upper surface of the second gate structure 125B. In some embodiments, height H_{C} of the upper surface of structure 125A is 10 nm or more (e.g., 15 nm) greater than height H_{D} of the upper surface of structure 125B. In some embodiments, height H_{C} of the upper surface of gate structure 125A is less (e.g., lower) than height H_{D} of the upper surface of structure 125B. The difference in heights H_{C}, H_{D} may be enabled by dielectric wall 140 between gate structures 125A, 125B and stacks 121A, 121B.

In the exemplary embodiment of FIG. 1A, the upper surfaces of walls 140 between (and to both sides of) gate structures 125A, 125B are at vertical position or height H_{C} (the greater or higher of heights H_{C}, H_{D}). In transistor structure 101A, the metal(s) of gate electrode 126 and the dielectric layer(s) 123 in structure 125A (e.g., on sidewalls 141, 142) extend up to height H_{C}. In transistor structure 101B, the metal(s) of gate electrode 126 and the dielectric layer(s) 123 in structure 125B (e.g., on sidewalls 141, 142) extend up to height H_{D}. Dielectric layer(s) 123 in structure 125B is not present on sidewalls 141, 142 above height H_{D}. A gate insulator layer 144 is over structure 125B, between heights H_{C}, H_{D}, and with a height equal to a difference in heights H_{C}, H_{D}. A gate via 129 is through gate insulator layer 144 over structure 125B.

The difference in heights H_{C}, H_{D} of structures 125A, 125B may be related to a difference in heights H_{A}, H_{B} of nanoribbons 120A, 120B, respectively. For example, nanoribbons 120A in stack 121A and structure 101A may have heights H_{A} offset from heights H_{B} of nanoribbons 120B in stack 121B and structure 101B, and heights H_{C}, H_{D} may be offset from nanoribbons 120A, 120B by a same vertical span. Height H_{C} is offset from an uppermost one of nanoribbons 120A by a vertical (span or distance or) height H₃, and height H_{D} is offset from an uppermost one of nanoribbons 120B by a vertical (span or distance or) height H₄. In the exemplary embodiment of FIG. 1A, vertical spans or heights H₃, H₄ are equal, e.g., with a same thickness of a respective gate structure 125 between an uppermost nanoribbon 120A, 120B and a corresponding gate via 129. In some embodiments, height H₃ is greater than height H₄, e.g., with a minimum thickness of gate electrode 126 in gate structure 125B over nanoribbons 120B. In some embodiments, height H₃ (e.g., a thickness of gate electrode 126 in gate structure 125A) is less or shorter than height H₄.

As in the exemplary embodiment shown in FIG. 1A, first heights H_{A1}-H_{A4} of first nanoribbons 120A may be offset and interleaved with second heights H_{B1}-H_{B4} of second nanoribbons 120B. For example, an uppermost first height H_{A1} of an uppermost nanoribbon 120A is greater than (e.g., above) an uppermost second height H_{B1} of an uppermost nanoribbon 120B. Each adjacent pair of second nanoribbons 120B includes upper and lower nanoribbons 120B, with the upper nanoribbon 120B having a first axis (e.g., centerline) at a first height H_{BX} above a second axis at a second height H_{A(X+1)} of an adjacent first nanoribbon 120A and the lower second nanoribbon 120B with a third axis at a third height H_{B(X+1)} below the second axis of the adjacent nanoribbon 120A. Each adjacent pair of first nanoribbons 120A includes upper and lower nanoribbons 120A, with the upper nanoribbon 120A having a first axis at a first height H_{AX} above a second axis at a second height H_{BX} of an adjacent second nanoribbon 120B and the lower nanoribbon 120A with a third axis at a third height H_{A(X+1)} below the second axis of the adjacent first nanoribbon 120A.

Stacks 121A, 121B may have any suitable number of nanoribbons 120A, 120B. In the exemplary embodiments of FIG. 1A, etc., stacks 121A, 121B each have four nanoribbons 120A, 120B, but stacks 121A, 121B may have more or fewer nanoribbons 120A, 120B. In some embodiments, stacks 121A, 121B each have three (or fewer) nanoribbons 120A or 120B. In other embodiments, stacks 121A, 121B each have five (or more) nanoribbons 120A or 120B. In some embodiments, stack 121A has more (or fewer) nanoribbons 120A than stack 121B has nanoribbons 120B.

In the exemplary embodiment of FIG. 1A, nanoribbons 120A, 120B are evenly spaced in alternating fashion, with each of first nanoribbons 120A a constant interval above (e.g., at a higher height H_{A} than) corresponding second nanoribbons 120B (e.g., at a lower height H_{B}), which are the constant interval above the next nanoribbon 120A. In many embodiments, as in FIG. 1A, stacks 121A, 121B have equal and constant pitches H_{Pa}, H_{Pb}. A vertical pitch H_{Pa} between nanoribbons 120A in stack 121A (the identical differences between heights H_{A1}, H_{A2}; between heights H_{A2}, H_{A3}; and between heights H_{A3}, H_{A4}) is equal to a vertical pitch H_{Pb} between nanoribbons 120B in stack 121B (the identical differences between heights H_{B1}, H_{B2}; between heights H_{B2}, H_{B3}; and between heights H_{B3}, H_{B4}). In the context of pitches, heights (whether vertical positions or spans), thicknesses, etc., of nanoribbons 120, dimensions (e.g., heights, etc.) are considered approximately equal if the dimensions are within 1 nm. Nanoribbons 120B (except for the lowest nanoribbon 120B) are vertically centered between nearest-neighbor nanoribbons 120A (e.g., a half-pitch above and below the nearest-neighbor nanoribbons 120A). Nanoribbons 120A (except for the highest nanoribbon 120A) are vertically centered between nearest-neighbor nanoribbons 120B (e.g., a half-pitch above and below the nearest-neighbor nanoribbons 120B).

Heights H_{A1}-H_{A4}, H_{B1}-H_{B4} are vertical positions of nanoribbons 120A, 120B referenced to axes or centerlines of nanoribbons 120A, 120B, but nanoribbons 120A, 120B may be otherwise referenced (e.g., to upper or lower surfaces of nanoribbons 120A, 120B) with the same resultant interleaving (e.g., ordering) of heights H_{A1}-H_{A4}, H_{B1}-H_{B4}. In some embodiments, the lower surface of each of nanoribbons 120A, 120B in stacks 121A, 121B is coplanar with an upper surface of the lower nearest-neighbor nanoribbon 120B, 120A in the other stack 121B, 121A. For example, nanoribbons 120A, 120B in stacks 121A, 121B may come from a same stack of alternating layers (e.g., with each type of nanoribbon 120A or 120B having a different layer composition), and nearest-neighbor nanoribbons 120A, 120B in opposite stacks 121A, 121B may come from layers that had previously been adjoining. In some other embodiments (e.g., with thinner nanoribbons 120A and/or 120B), the lower surface of each of nanoribbons 120A, 120B in stacks 121A, 121B is above an upper surface of the lower nearest-neighbor nanoribbon 120B, 120A in the other stack 121B, 121A. As in many embodiments, nanoribbons 120A have a thickness T_{A} equal to a thickness T_{B} of nanoribbons 120B.

In many embodiments, vertical spans or heights H₁, H₂ of stacks 121A, 121B are equal. In the exemplary embodiment of FIG. 1A, vertical spans or heights H₁, H₂ span from a lower surface of a lowest nanoribbon 120A, 120B to an upper surface of a highest nanoribbon 120A, 120B in stacks 121A, 121B, respectively.

Transistor structures 101A, 101B may be of the same or of complementary conductivity types (e.g., NMOS and/or PMOS structures 101A, 101B). In the exemplary embodiment of FIG. 1A, transistor structure 101A is an n-type structure 101A, and transistor structure 101B is a p-type structure 101B. In other embodiments, transistor structure 101A a p-type structure 101A, and transistor structure 101B is an n-type structure 101B. In still other embodiments, both of transistor structures 101A, 101B are of the same conductivity type (e.g., both PMOS structures 101A, 101B or both NMOS structures 101A, 101B).

Dielectric wall 140 may enable the independent processing of stacks 121A, 121B of nanoribbons 120A, 120B in transistor structures 101A, 101B, which allows for structures 101A, 101B with nanoribbons 120A, 120B of different heights, thicknesses, compositions, etc. For example, nanoribbons 120 may have any suitable width (e.g., in the y-dimension) and may be, e.g., nanowire nanoribbons 120 or nanosheet nanoribbons 120. Deploying nanoribbons 120A, 120B of different material compositions may improve performance by allowing the employment of optimal materials for different transistor structures 101. In many embodiments, transistor structures 101A, 101B are of complementary conductivity types (e.g., n-and p-types). In many embodiments, structure 101A is an n-type transistor structure 101A. In many embodiments, first nanoribbons 120A are predominantly silicon. In many embodiments, structure 101B is a p-type transistor structure 101B. In many embodiments, second nanoribbons 120B include silicon and germanium. Nanoribbons 120 provide channel regions for transistor structures 101 and may be of any (e.g., semiconducting) material(s) suitable for use as channel regions. Nanoribbons 120A in stack 121A may be the same or different than nanoribbons 120B in stack 121B.

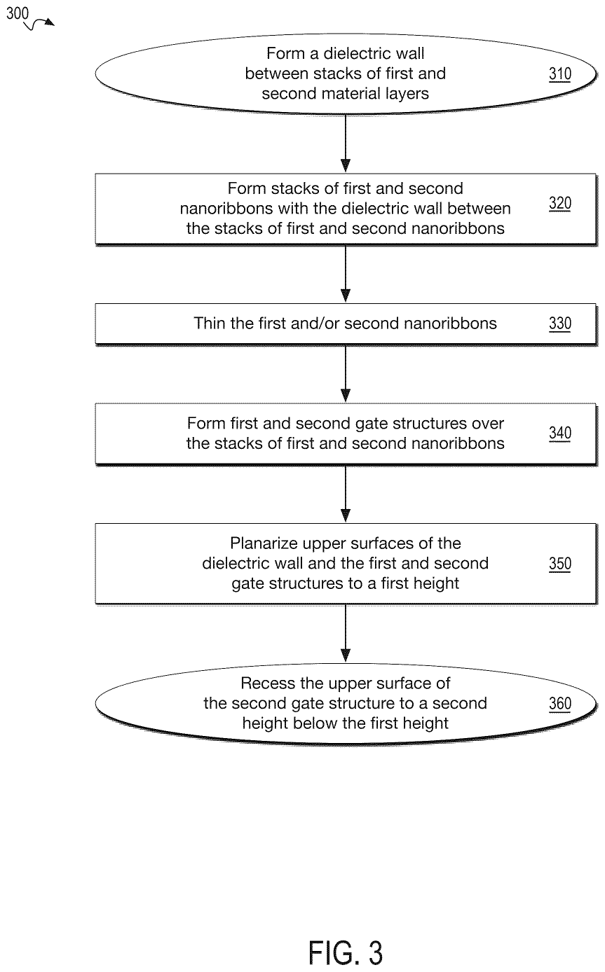

Isolation wall 140 is a dielectric structure on (e.g., in contact with) both of structures 125A, 125B. Wall 140, separating gate structures 125A, 125B, extends vertically from above the tops (e.g., upper surfaces) of gate electrodes 126 to below the bottoms (e.g., lower surfaces) of electrodes 126. Dielectric wall 140 provides isolation (e.g., electrical isolation) between gate electrodes 126 of structures 101A, 101B. A thin wall 140 enables the tight packing of transistor structures 101A, 101B and gate electrodes 126 in device 100. Dielectric wall 140 also enables the independent processing of gate structures 125A, 125B in structures 101A, 101B (e.g., as described elsewhere herein, such as at FIG. 3 and methods 300), which allows for structures 125 having different insulator layers 122, 123, etc., for example, with different thicknesses, materials, etc. Each wall 140 is between a pair of gate electrodes 126, and each electrode 126 is between a pair of dielectric walls 140.

In some embodiments, as in the exemplary embodiment of FIG. 1A, transistor structures 101A, 101B have different gate stacks in adjacent gate structures 125A, 125B separated by slim dielectric wall 140. For example, structures 125A, 125B may have different gate dielectric layers 123A, 123B or metal layers 127, 128 (e.g., to advantageously provide different threshold voltages V_{T} for transistor structures 101A, 101B). The different gate stacks in gate structures 125A, 125B and transistor structures 101A, 101B are shown in greater detail in views 102, 103, respectively.

Transistor structure 101A includes a first stack 121A of first nanoribbons 120 extending through first gate structure 125A. Transistor structure 101B includes a second stack 121B of second nanoribbons 120 extending through second gate structure 125B. Structures 125A, 125B have different first and second gate stack compositions. The difference between the first and second compositions of structures 125A, 125B, respectively, may be that structures 125A, 125B include a different quantity of layers (e.g., more or different layers), similar layers but with different materials, etc. Gate structures 125A, 125B may have different dielectric stacks 124 (e.g., stacks 124A, 124B). For example, first and second compositions of gate structures 125A, 125B may differ by only (exactly) one of structures 125A, 125B having a high-k dielectric layer 123 on a transition layer 122.

First gate structure 125A includes a first dielectric stack 124A on first nanoribbons 120, and gate structure 125A includes one or more first metal layers 127 on dielectric stack 124A. View 102 shows an embodiment having multiple layers 127 on stack 124A. First dielectric stack 124A includes dielectric layers 122A on first nanoribbons 120A and insulator layers 123A around nanoribbons 120A, on dielectric layers 122A. First gate structure 125A may also include a metal (e.g., fill) layer 128 on liner layer 127.

Second gate structure 125B includes a second dielectric stack 124B on second nanoribbons 120 (as illustrated at view 103), and gate structure 125B includes one or more second metal layers 127 on dielectric stack 124B. Second dielectric stack 124B includes dielectric layers 122B on second nanoribbons 120B and insulator layers 123B around nanoribbons 120B, on dielectric layers 122B. Second gate structure 125B may also include a metal (e.g., fill) layer 128 on liner layer 127.

Dielectric layers 122 (e.g., layers 122A, 122B) may include any suitable material(s) and may have any suitable thickness(es). Layers 122A, 122B are on nanoribbons 120 in transistor structures 101A, 101B, respectively, and may provide protection to nanoribbons 120, e.g., during processing. For example, layers 122A, 122B may be passivation layers 122A, 122B, e.g., of a native oxide of a material in nanoribbons 120. In many embodiments, dielectric layers 122 include silicon and oxygen. Layers 122A, 122B may be transition layers 122 between nanoribbons 120 and other layers (such as layers 123, etc.) over layers 122. In some embodiments, dielectric layers 122A, 122B have thicknesses T₁, T₂ less than thicknesses of other layers over layers 122A, 122B. In many embodiments, dielectric layers 122A have a thickness T₁ greater than (or less than) a thickness T₂ of dielectric layers 122B. In some embodiments, one of layers 122A, 122B includes a material not included in the other of layers 122A, 122B. Layers 122 may include other suitable materials. Different thicknesses T₁ or T₂ (or different material compositions) of layers 122A, 122B may provide different threshold voltages V_{T} for transistor structures 101A, 101B. Different thicknesses T₁ or T₂ of layers 122A, 122B may provide different thicknesses of nanoribbons 120 in transistor structures 101A, 101B.

Insulator layers 123 (e.g., layers 123A, 123B) may include any suitable material(s) and may have any suitable thickness(es). Layers 123A, 123B are on transition layers 122A, 122B in transistor structures 101A, 101B, respectively. In many embodiments, insulator layers 123A, 123B have thicknesses T₃, T₄ greater than thicknesses T₁, T₂ of layers 122A, 122B on nanoribbons 120. Insulator layers 123 may be dielectric layers 123. For example, layers 123A, 123B advantageously include one or more high-k dielectric materials, which may provide design flexibility and/or superior characteristics (such as electrical characteristics) when deployed with, or instead of, other materials.

Layers 123 (e.g., high-k layers 123A, 123B) may allow for a greater transconductance gₘ (e.g., for a same voltage on gate electrode 126 and same thickness T₃ or T₄) in transistor structures 101A, 101B. High-k layers 123 may allow for greater total thicknesses (e.g., thickness T₁ plus thickness T₃ in stack 124A or thickness T₂ plus thickness T₄ in stack 124B) of dielectric over nanoribbons 120, and so may enable low leakage currents in structures 101A, 101B (e.g., for a same voltage on gate electrode 126 while maintain a same transconductance gₘ). High-k layers 123A, 123B may enable low leakage currents in structures 101A, 101B, e.g., with a lower voltage on gate electrode 126 and a same thickness T₃ or T₄. In many embodiments, insulator layers 123A have a thickness T₃ greater than (or less than) thickness T₄ of insulator layers 123B. Different thicknesses T₃ or T₄ (or different material compositions) of layers 123A, 123B may provide different threshold voltages V_{T} for transistor structures 101A, 101B.

Insulator layers 123 may include any suitable material(s). In many embodiments, insulator layers 123 include hafnium and oxygen. In some embodiments, insulator layers 123 include zirconium and oxygen. In some embodiments, insulator layers 123 include hafnium, zirconium, and oxygen. In some embodiments, insulator layers 123A, 123B have different material compositions. In some embodiments, for example, insulator layers 123A (or layers 123B) include hafnium and zirconium, and insulator layers 123B (or layers 123A) include neither, or only one, of hafnium and zirconium (e.g., hafnium but not zirconium, or zirconium but not hafnium). In some embodiments, layers 123A, 123B both include hafnium, zirconium, and oxygen (HZO, e.g., in hafnium zirconate or hafnium zirconium oxide), but at different elemental ratios. The material compositions of one or both of layers 123A, 123B (e.g., the ratio of hafnium to zirconium) may be varied to increase a relative permittivity of layer 123A and/or 123B (e.g., from about 1:1 to about 2:1 or more). In some embodiments, a dopant (e.g., yttrium) is added to one or both of layers 123A, 123B to increase a relative permittivity of layer 123A and/or 123B (e.g., by increasing a proportion of higher-permittivity dielectric phase in layer(s) 123). Either or both of layers 123A, 123B may include one or more of various elements, such as hafnium, zirconium, silicon, oxygen, titanium, tantalum, lanthanum, aluminum, barium, strontium, yttrium, scandium, niobium, and zinc. Layers 123 may include other suitable materials.

First and second gate structures 125A, 125B may include a dipole dopant. In some embodiments, one of first and second gate structures 125A, 125B includes a dipole dopant not present in the other of gate structures 125A, 125B. In some embodiments, first and second gate structures 125A, 125B include a same dipole dopant, but the dipole dopant is present at a first height (e.g., of a sum of thicknesses T₁, T₃) from nanoribbons 120 in stack 121A greater (or lesser) than a second height (e.g., of a sum of thicknesses T₂, T₄) from nanoribbons 120 in stack 121B. The same dipole dopant may be within different layers 122, 123 (or at a different interface of layers 122, 123) in the different dielectric stacks 124A, 124B.

Gate electrodes 126 (and gate structures 125A, 125B) may include one or more metal layers 127, 128. Gate electrodes 126, together with first and second dielectric stacks 124A, 124B, form first and second gate structures 125A, 125B for electrostatically controlling the conduction of transistor structures 101A, 101B. Layers 127, 128 may be workfunction metal (WFM) layers 127, 128, for example, to (e.g., independently) influence threshold voltages V_{T} of transistor structures 101A, 101B. Layers 127 may be conformal, liner layers 127 around nanoribbons 120 and dielectric stacks 124, e.g., with a first metal layer 127 on insulator layer 123A around each of nanoribbons 120 in structure 101A and a second metal layer 127 on insulator layer 123B around each of nanoribbons 120 in structure 101B. Transistor structure 101A and gate structure 125A may include one or more metal layers 127 in electrode 126. Transistor structure 101B and gate structure 125B may include one or more metal layers 127 in electrode 126.

Liner layers 127 in structures 101A, 101B may have different thicknesses T₅, T₆, respectively, for example, with a thickness T₅ (or thickness T₆) greater than a thickness T₆ (or thickness T₅) and having a correspondingly larger impact on the threshold voltage V_{T} of transistor structure 101A (or structure 101B). Layers 127 in structures 101A, 101B may have the same or different material compositions. Fill layers 128 in structures 101A, 101B may have different material compositions. Layers 127, 128 may include any suitable material(s), including non-metals. In many embodiments, layers 127 include nitrogen (e.g., in a metal nitride) or carbon (e.g., in a metal carbide). In some such embodiments, layers 127 include nitrogen and titanium, molybdenum, or tantalum. In some embodiments, a first layer 127 on a dielectric stack 124 includes titanium and nitrogen, and a second layer 127 on first layer 127 includes nitrogen and tantalum or molybdenum. In some embodiments, layer 127 includes titanium, aluminum, and carbon. In many embodiments, layer 128 includes tungsten.

Wall 140 includes opposing first and second sides or sidewalls 141, 142. A width W₁ (or width W₂) of dielectric wall 140 separates sidewalls 141, 142. Width W₁ (or width W₂) separates gate structures 125A, 125B in transistor structures 101A, 101B, respectively. Dielectric wall 140 (e.g., sidewalls 141, 142) may be nearly vertical. In many embodiments, dielectric wall 140 has widths W₁, W₂ differing only slightly (e.g., in a tapering profile that narrows slightly upwards or downwards. For example, widths W₁, W₂ may be within 1 nm. Width W₁ is defined as the width of wall 140 at a top of wall 140. Width W₂ is defined as the width of wall 140 at a bottom of structures 125, e.g., where wall 140 meets substrate 199 at a bottom of a gate structure 125.

Gate structures 125 are separated by dielectric wall 140 and a minimum distance or width W₂ (or width W₁, etc.) between structures 125. In many embodiments, dielectric wall 140 has a minimum width W₂ (or width W₁, etc.) of 12 nm or less between structures 125, which may enable sufficiently tight packing of transistor structures 101A, 101B and a consequent conservation of layout area. In some embodiments, dielectric wall 140 has a minimum width W₂ (or width W₁, etc.) of 10 nm or less between structures 125, which may enable superior packing of transistor structures 101A, 101B and conservation of layout area. Such (small widths W₁, W₂ and) tight laying out of structures 101 may be enabled by a fine, high aspect ratio etch (e.g., through and between metal gate electrodes 126).

The tight packing of stacks 121 and transistor structures 101 may also be characterized by a small distance D separating the first and second stacks 121A, 121B of nanoribbons 120. In many embodiments, distance D is less than three times a maximum width W₁ of wall 140. For example, if wall 140 is centered between stacks 121 and in distance D, wall 140 is less than a width W₁ from either stack.

Isolation wall 140 includes any suitable material(s), for example, a dielectric material. Wall 140 advantageously includes a low-k (low-permittivity) dielectric material. Wall 140 advantageously has an etch selectivity with other adjacent structures. In many embodiments, wall 140 includes silicon and nitrogen (e.g., in a nitride of silicon). In some embodiments, wall 140 includes silicon and oxygen (e.g., in an oxide of silicon). In some embodiments, wall 140 includes carbon and/or nitrogen, for example, in addition to silicon and oxygen.

Isolation wall 140 may enable the independent processing of gate structures 125A, 125B in structures 101A, 101B (e.g., as described at least at FIG. 3 and methods 300), which allows for structures 125 of various compositions (e.g., having layers 122, 123, 127, etc., of different thicknesses T₁, T₂, T₃, T₄, T₅, T₆, and/or including different materials).

At least some of the layers of structures 125A, 125B around nanoribbons 120 are also on sidewalls 141, 142 of isolation wall 140. Insulator layer 123A is on sidewall 141. Insulator layer 123B is on sidewall 142. In transistor structure 101A, metal layer 127 is on insulator layer 123A on sidewall 141. In transistor structure 101B, metal layer 127 is on insulator layer 123B on sidewall 142. Notably, gate dielectric layers 122A, 122B on nanoribbons 120 may be absent from sidewalls 141, 142 of isolation wall 140, as in the exemplary embodiment of FIG. 1A. In many embodiments, for any given gate structure 125, the layer 123 on sidewalls 141, 142 is continuous with the layers 123 around the nanoribbons 120 through the given structure 125. For example, the layers 123 may be a single layer, continuous or connected around the corresponding gate electrode 126, to both x-directions of the viewing plane.

Gate vias 129 are metallization structures that couple (e.g., electrically couple) gate electrodes 126, for example, with an interconnect network (not shown) above transistor structures 101. Vias 129 may include any suitable material(s), including non-metals. Vias 129 may include multiple layers of metals, for example, a liner (e.g., barrier or seed) layer around a fill layer. Gate vias 129 are through a dielectric layer 149 over transistor structures 101A, 101B. Dielectric layer 149 may be of any suitable material, such as a low-k dielectric material.

Substrate 199 may include any suitable material or materials. Substrate 199 may be an IC substrate, such as an IC die or wafer. In some examples, the substrate may include monocrystalline silicon (including silicon on insulator (SOI)), polycrystalline silicon, germanium, silicon germanium, a III-V alloy material (e.g., gallium arsenide), a silicon carbide (e.g., SiC), a sapphire (e.g., Al₂O₃), or any combination thereof. Substrate 199 may also include semiconductor materials, metals, dielectrics, dopants, and other materials commonly found in semiconductor substrates. Substrate 199 may refer specifically to a base material (for example, a thick base or layer of semiconductor material) that other materials (such as metals and dielectrics) are built up on. In some contexts, substrate 199 may refer to a base material layer and any build-up layers, etc., over the base. Transistor structures 101 may be over a dielectric layer over other (e.g., semiconductor) materials.

FIG. 1B illustrates cross-sectional plan and profile views 104, 105 of IC device 100, including dielectric wall 140 separating adjacent source or drain bodies 110A, 110B and gate structures 125A, 125B in transistor structures 101A, 101B, in accordance with some embodiments. Profile view 104 (similar to much of FIG. 1A, shown for reference) has a cross-sectional y-z viewing plane through gate structures 125A, 125B of transistor structures 101A, 101B. Plan view 105 has a cross-sectional x-y viewing plane through source or drain bodies 110A, 110B and gate electrodes 126 of gate and transistor structures 125A, 125B, 101A, 101B (e.g., under upper surfaces of structures 125A, 125B, below dielectric layer 144). Nanoribbons 120 (e.g., nanoribbons 120A, 120B) not in the viewing plane are shown (e.g., for reference) with dashed lines.

IC device 100 includes source or drain bodies 110A, 110B in front of or behind (e.g., in either x-direction) the gate electrodes 126 of structures 125A, 125B shown in profile view 104. Bodies 110A, 110B are to both x-directions of gate electrodes 126 in plan view 105. First transistor structure 101A includes first source or drain bodies 110A coupled with stack 121A of first nanoribbons 120A. Second transistor structure 101B includes second source or drain bodies 110B coupled with stack 121B of second nanoribbons 120B.

As shown in view 105, source or drain bodies 110 are electrically and physically coupled to opposite ends of channel-region nanoribbons 120. In many embodiments, transistor structures 101 are each physically symmetrical about nanoribbons 120 (e.g., channel regions) and gate electrodes 126, and identifiers “drain” and “source” for bodies 110 may be reversed interchangeably in many contexts. However, the classification of source or drain bodies 110 may be by the electrical relationships of transistor structures 101 and bodies 110 to other components in a given circuit (e.g., and the consequent direction of current flow through structures 101 and bodies 110). Some source or drain bodies 110 may simultaneously be a source body 110 in one transistor structure 101 and a drain body 110 in another transistor structure 101.

Source or drain bodies 110 may be impurity doped regions, e.g., regions of semiconductor material doped with one or more electrically active impurities and having increased charge-carrier availabilities and associated conductivities. Bodies 110 in different transistor structures 101 may be doped with an opposite type (e.g., n-or p-type) or of similar type. Source or drain bodies 110 may include a predominant semiconductor material, and one or more n-dopants (such as phosphorus, arsenic, or antimony) or p-type impurities (such as boron or aluminum). Other dopant materials may be used. Any suitable means of formation may be used. Bodies 110 may be epitaxially grown semiconductor regions, for example, of a Group IV semiconductor material (e.g., Si, Ge, SiGe, GeSn alloy). Other semiconductor materials may be employed. Bodies 110 may be substantially crystalline. Source or drain bodies 110 may be polycrystalline or substantially monocrystalline, e.g., having long-range order at least adjacent ends of nanoribbons 120 and merging or joining into a unitary body with few grain boundaries.

Source or drain bodies 110A, 110B may be of different materials, for example, to improve performance in complementary transistor structures 101A, 101B. In many embodiments, structure 101A is an n-type transistor structure 101A, and body 110A is predominantly silicon. In many embodiments, structure 101B is a p-type transistor structure 101B, and body 110B includes silicon and germanium.

As shown in view 105, dielectric wall 140 is between source or drain bodies 110A, 110B. Wall 140 includes opposing first and second sidewalls 141, 142, and dielectric wall 140 is in direct contact with bodies 110A, 110B at sidewalls 141, 142. As shown in view 105, dielectric wall 140 is between stacks 121A, 121B of first and second nanoribbons 120A, 120B, gate electrodes 126, and source or drain bodies 110A, 110B. Dielectric wall 140 extends through spacers 147. Gate dielectric layer 123 is on electrodes 126 (e.g., in a gate stack or structure 125 with gate electrode 126) and on dielectric wall 140 (e.g., at sidewalls 141, 142) and spacers 147. Dielectric wall 140 is an isolation structure, e.g., providing electrical isolation between electrodes 126 and between bodies 110A, 110B. Other gate electrodes 126, etc., not shown, are in other transistor structures 101 just beyond edges of view 105 (e.g., in the x-directions).

Spacers 147 (as illustrated at view 105) are isolation structures, e.g., of insulator material (such as a low-k dielectric), adjacent gate electrodes 126 and source or drain bodies 110. Spacers 147 provide isolation (e.g., electrical isolation) between electrodes 126 and bodies 110.

FIG. 1C illustrates cross-sectional profile views of device 100 with dielectric wall 140 between nanoribbons 120A, 120B of different materials and heights in transistor structures 101A, 101B, in accordance with some embodiments. Views 106, 107 show gate structure 125A between dielectric walls 140 and source or drain bodies 110A in transistor structure 101A. Views 108, 109 illustrate gate structure 125B between dielectric walls 140 and source or drain bodies 110B in transistor structure 101B. Dielectric wall 140 (not shown in views 107, 109 of FIG. 1C) is between stacks 121 of nanoribbons 120 in transistor structures 101A, 101B (as shown at FIGS. 1A and 1B). Spacers 148 (e.g., spacers 148A, 148B) are between gate structures 125 and source and drain bodies 110.

Views 106, 107 are y-z and x-z cross-sectional profile views of gate structure 125A, source or drain bodies 110A, and nanoribbons 120A in transistor structure 101A. View 106 shows a portion of FIG. 1A (e.g., of transistor structure 101A) and provides a reference for x-z cross-sectional profile view 107 through nanoribbons 120A. Views 106, 107 are vertically aligned, for example, with heights H_{A1}-H_{A4} of nanoribbons 120A aligned between views 106, 107. As in FIG. 1A, heights H_{A1}-H_{A4} of nanoribbons 120A are offset from (and interleaved with) heights H_{B1}-H_{B4} of nanoribbons 120B. Spacers 147 are over nanoribbons 120A. Spacers 148A are between and under nanoribbons 120A. In some embodiments, spacers 147, 148A have different compositions, as in FIG. 1C.

Views 108, 109 are y-z and x-z cross-sectional profile views of source or drain bodies 110B and nanoribbons 120B in transistor structure 101B. View 108 shows a portion of FIG. 1A (e.g., of transistor structure 101B) and provides a reference for x-z cross-sectional profile view 109 through nanoribbons 120B. Views 108, 109 are vertically aligned, for example, with heights H_{B1}-H_{B4} of nanoribbons 120B aligned between views 108, 109. As in FIG. 1A, heights H_{A1}-H_{A4} of nanoribbons 120A are offset from (and interleaved with) heights H_{B1}-H_{B4} of nanoribbons 120B. Spacers 147 are over nanoribbons 120B. Spacers 148B are between and under nanoribbons 120B. In some embodiments, spacers 147, 148B have different compositions, as in FIG. 1C.

First and second gate electrodes 126 in transistor structures 101A, 101B, respectively, may be different or substantially similar. Gate electrodes 126 may include metal layers (including layers 127), which may be different or substantially similar in transistor structures 101A, 101B. Gate electrodes 126 may be part of gate structures 125 that also include dielectric layers 123, which are on electrodes 126 and on spacers 147, 148A, 148B. Gate dielectric layers 123 insulate channel regions of nanoribbons 120A, 120B from electrodes 126 and may be different or substantially similar in transistor structures 101A, 101B. (Nanoribbons 120 may also have other dielectric layers, such as passivation layers on nanoribbons 120A, 120B, insulating channel regions of nanoribbons 120A, 120B from electrodes 126.)

Spacers 147, 148A, 148B are isolation structures, e.g., of insulator material (such as a low-k dielectric material), adjacent gate electrodes 126. Spacers 148 provide isolation between electrodes 126 and bodies 110. Spacers 147 provide isolation between electrodes 126 and bodies 110 and contact structures 119 over bodies 110. Dielectric wall 140 may enable the independent processing of spacers 148A, 148B adjacent stacks 121A, 121B and so the use of different (e.g., optimized) materials in spacers 148A, 148B. In many embodiments, the dielectric material(s) of spacers 148A, 148B have mutual etch selectivities.

As shown in view 107, first transistor structure 101A includes first gate electrode 126 with first cavity spacer 148A between first gate electrode 126 and source or drain body 110A and between adjacent nanoribbons 120A in structure 101A. As shown in view 109, second transistor structure 101B includes second gate electrode 126 with second cavity spacer 148B between second gate electrode 126 and source or drain body 110B and between adjacent nanoribbons 120B in structure 101B. In many embodiments, first and second cavity spacers 148A, 148B have different compositions. In some embodiments, spacers 148A, 148B have etch selectivities. In some embodiments, nanoribbons 120A, 120B are of different compositions, and spacers 148A, 148B are of different compositions, e.g., optimized for use as cavity spacers 148 adjacent nanoribbons 120A, 120B of different compositions. For example, spacers 148A, 148B may each be compositionally different dielectric materials that, during fabrication, deposit selectively on different sacrificial materials between nanoribbons 120A, 120B, respectively. In some embodiments, nanoribbons 120A are predominantly silicon, and spacers 148A are of a dielectric material that deposits on SiGe (e.g., sacrificial material) selective to Si, SiOC, SiOCN, SiO surfaces. In some embodiments, nanoribbons 120B include silicon and germanium, and spacers 148B are of a dielectric material that deposits on Si (e.g., sacrificial material) selective to SiGe surfaces.

Gate vias 129 contact gate structures 125A, 125B through dielectric layer 149 over transistor structures 101A, 101B. Gate via 129 over transistor structure 101B is through dielectric layer 144.

Source and drain contact structures 119 (e.g., via structures 119) are metallization structures 119 that couple (e.g., electrically couple) bodies 110, for example, with an interconnect network (not shown) above transistor structures 101. Contact structures 119 may include any suitable material(s), including non-metals. For example, contact structures 119 may include an interface (e.g., silicide) layer on bodies 110. Structures 119 may include multiple layers of metals, for example, a liner (e.g., barrier or seed) layer around a fill layer. Contact structures 119 are through dielectric layer 149 over transistor structures 101A, 101B and through a dielectric layer 114 over bodies 110, between bodies 110 and layer 149. Dielectric layers 114, 149 may be of any suitable material(s), such as a low-k dielectric material.

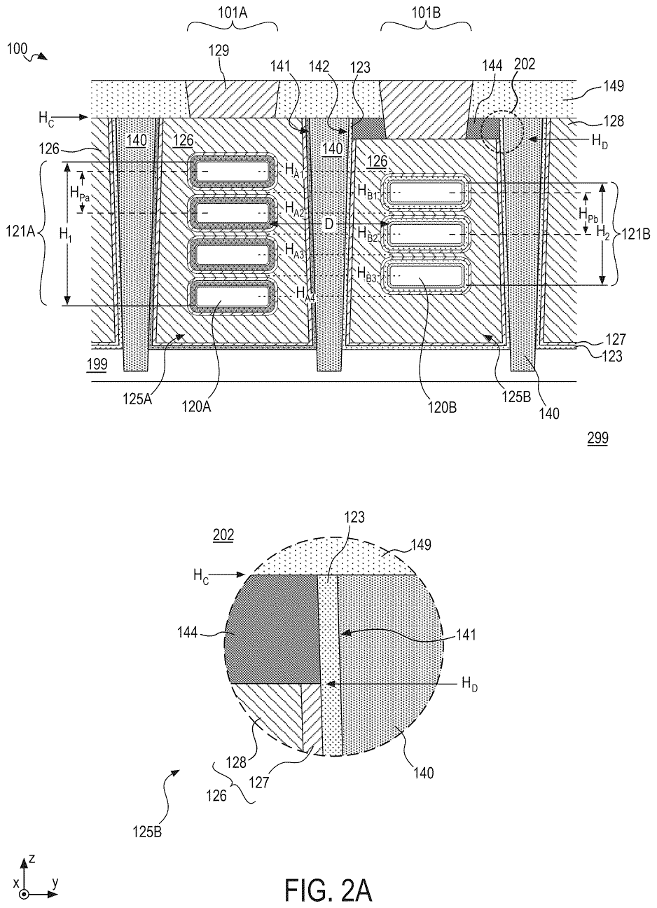

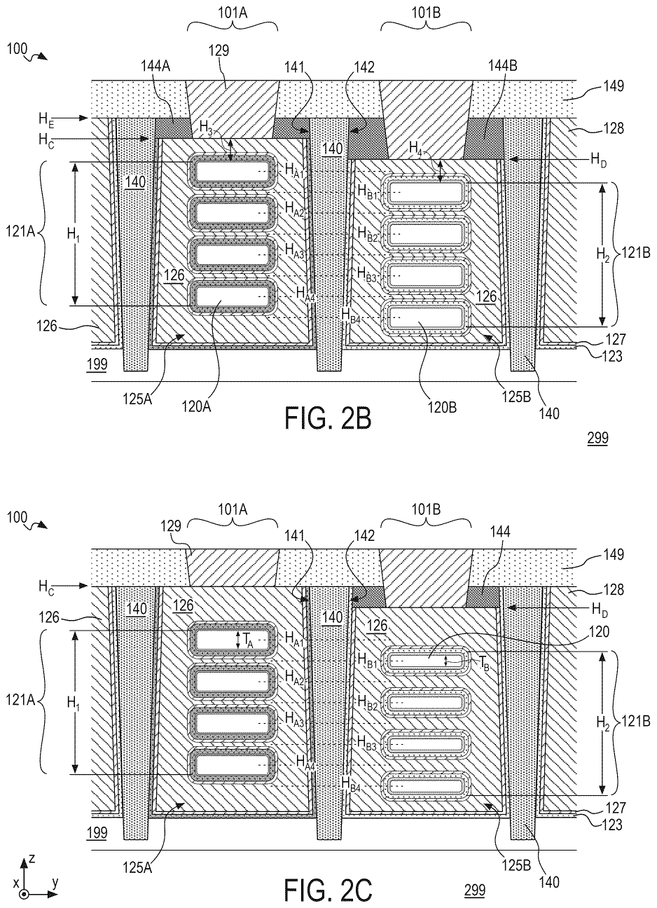

FIGS. 2A, 2B, and 2C illustrate cross-sectional profile views of IC device 100 with transistor structures 101A, 101B having gate structures 125A, 125B with different gate heights H_{C}, H_{D} and separated by dielectric wall 140, in accordance with some embodiments. FIGS. 2A, 2B, and 2C show embodiments similar to, e.g., those illustrated at FIG. 1A, but with notable differences. FIG. 2A shows an embodiment with dielectric layer 123 of gate structure 125A on sidewalls 141, 142 above height H_{D}, extending beyond gate electrode 126. FIG. 2B shows an embodiment with upper surfaces of gate structure 125A, 125B at heights H_{C}, H_{D} below the upper surfaces of dielectric walls 140 at height H_{E}. FIG. 2C illustrates an embodiment with upper surfaces of gate structure 125A, 125B at heights H_{C}, H_{D} above corresponding nanoribbons 120A, 120B with different heights H_{A}, H_{B} and thicknesses T_{A}, T_{B}, respectively.

FIG. 2A shows transistor structure 101A with the metal(s) of gate electrode 126 and the dielectric layer(s) 123 in structure 125A (e.g., on sidewalls 141, 142) extending up to height H_{C}. In transistor structure 101B, the metal(s) of gate electrode 126 in structure 125B extend up to height H_{D}. The dielectric layer(s) 123 in structure 125B (e.g., on sidewalls 141, 142) extend up to and above height H_{D}, e.g., extending up to height H_{C}. Dielectric layer(s) 123 in structure 125B is present on sidewalls 141, 142 above height H_{D}. In the exemplary embodiment of FIG. 2A, the upper surfaces of walls 140 between (and to both sides of) gate structures 125A, 125B are at vertical position or height H_{C} (the greater or higher of heights H_{C}, H_{D}).

View 202 is shown at greater magnification and illustrates dielectric layer 144 over gate electrode 126 of gate structure 125B at sidewall 141 of dielectric wall 140. Layer 144 is between heights H_{C}, H_{D}, over gate electrode 126, which extends up to height H_{D}. Gate electrode 126 includes layers 127, 128, which both extend up to only height H_{D}. Gate dielectric layer 123 of gate structure 125B is up to height H_{C} on sidewall 141 of dielectric wall 140, up to and above height H_{D}. Layer 123 is between dielectric layer 144 and sidewall 141 of dielectric wall 140 (e.g., between heights H_{C}, H_{D}).

Notably, stack 121B has fewer nanoribbons 120B than stack 121A has nanoribbons 120A. In some embodiments, stack 121A has fewer nanoribbons 120A than stack 121B has nanoribbons 120B. In the exemplary embodiment of FIG. 2A, span height H₂ is shorter than span height H₁. Stacks 121A, 121B have equal pitches H_{Pa}, H_{Pb}.

IC device 100 may include or be coupled to a substrate or other host component 299. Host component 299 may be a package substrate, an interposer, an IC die, etc. For example, substrate 199 may be an IC die that includes transistor structures 101, substrate 199 may be coupled (e.g., soldered or otherwise bonded) to host component 299, and device 100 and transistor structures 101 may be coupled to a power supply (not shown) by host component 299.

Host component 299 is a planar platform and may include dielectric and metallization structures. Host component 299 mechanically supports and electrically couples one or more IC devices 100. At least one side of host component 299 includes substrate interconnect interfaces for bonding to one or more IC devices 100. IC device 100 may be direct bonded, e.g., hybrid bonded, to host component 299 or otherwise bonded, e.g., by optional solder bumps. The opposite side of host component 299 may include similar interfaces, e.g., copper pads for socketing and/or solder bumps for bonding device 100 to a host component, such as a printed circuit board (PCB). Host component 299 may be any host component with substrate interconnect interfaces, such as a package host component 299 or interposer, etc. Host component 299 may itself be a die. In many embodiments, host component 299 includes organic dielectric(s), such as a resin or other polymer, between metallization layers.

FIG. 2B illustrates the upper surfaces of walls 140 between (and to both sides of) gate structures 125A, 125B at a vertical position or height H_{E}, above or higher than both of heights H_{C}, H_{D}. In transistor structure 101A, the metal(s) of gate electrode 126 and the dielectric layer(s) 123 in structure 125A (e.g., on sidewalls 141, 142) extend up to height H_{C}, which is below height H_{E} and above heights H_{C}. Dielectric layer(s) 123 in structure 125A is not present on sidewalls 141, 142 above height H_{C}. A gate insulator layer 144A is over structure 125A, between heights H_{C}, H_{E} and with a height equal to a difference in heights H_{C}, H_{E}. In transistor structure 101B, the metal(s) of gate electrode 126 and the dielectric layer(s) 123 in structure 125B (e.g., on sidewalls 141, 142) extend up to height H_{D}, which is below both heights H_{C}, H_{E}. Dielectric layer(s) 123 in structure 125B is not present on sidewalls 141, 142 above height H_{D}. A gate insulator layer 144B is over structure 125B, between heights H_{D}, H_{E} and with a height equal to a difference in heights H_{D}, H_{E} (greater than a height of layer 144A equal to a difference in heights H_{C}, H_{E}).

In many embodiments, height H₃ (e.g., a thickness of gate electrode 126 in gate structure 125A) is equal to height H₄ (e.g., a thickness of gate electrode 126 in gate structure 125B), for example, with heights H₃, H₄ equal to a minimum allowable thickness of gate electrode 126 over respective nanoribbons 120A, 120B. In some embodiments, height H₃ (e.g., a thickness of gate electrode 126 in gate structure 125A) is less or shorter than height H₄ (e.g., a thickness of gate electrode 126 in gate structure 125B). In some such embodiments, heights H_{C}, H_{D} are approximately equal, below height H_{E}, for example, with substantially similar gate insulator layers 144A, 144B over gate structures 125A, 125B and with upper surfaces of layers 144A, 144B coplanar with upper surfaces of wall 140.

FIG. 2C shows transistor structures 101A, 101B with the metal(s) of gate electrodes 126 in structures 125A, 125B extending up to heights H_{C}, H_{D}, respectively. Height H_{C} of electrode 126 in structure 125A is greater than height H_{D} of electrode 126 in structure 125B, and heights H_{A} of nanoribbons 120A through gate structure 125A are greater than corresponding heights H_{B} of nanoribbons 120B through gate structure 125B. Nanoribbons 120A through gate structure 125A have thickness T_{A} greater than thickness T_{B} of nanoribbons 120B through gate structure 125B. In other embodiments, nanoribbons 120B through gate structure 125B have thickness T_{B} greater than thickness T_{A} of nanoribbons 120A through gate structure 125A. The difference in heights H_{A}, H_{B}, H_{C}, H_{D} and thicknesses T_{A}, T_{B} may be enabled by dielectric wall 140 between structures 125A, 125B and stacks 121A, 121B.

FIG. 3 is a flow chart of methods 300 for forming nanoribbon channel and gate structures with different heights and compositions, in accordance with some embodiments. Methods 300 include operations 310-360. Some operations shown in FIG. 3 are optional. Additional operations may be included. FIG. 3 shows an example sequence, but the operations can be done in other orders as well, and some operations may be omitted. Some operations can also be performed multiple times before other operations are performed. For example, many dielectric walls and many nanoribbons stacks may be formed before any gate structures are recessed. Some operations may be included within other operations so that the number of operations illustrated FIG. 3 is not a limitation of the methods 300.

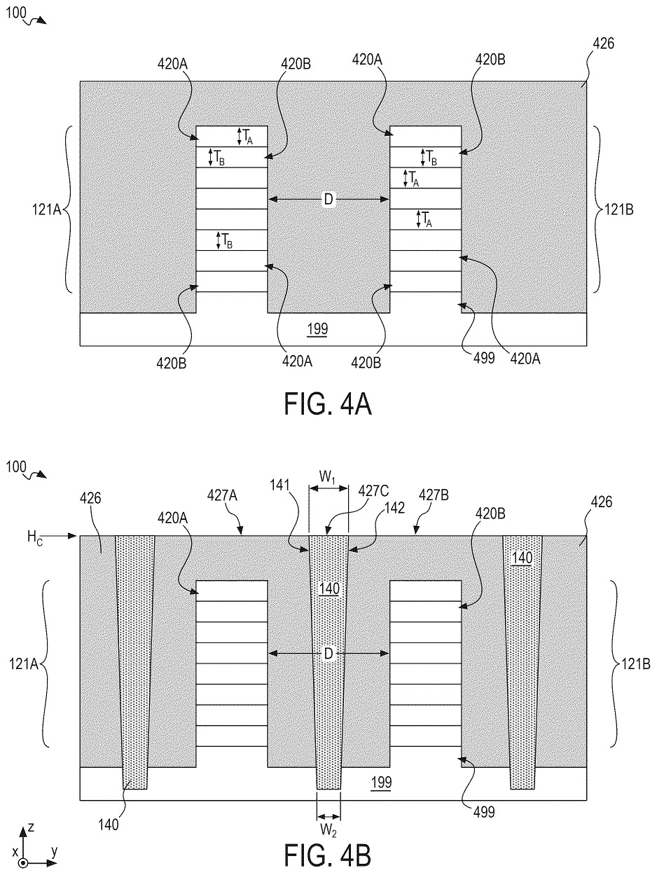

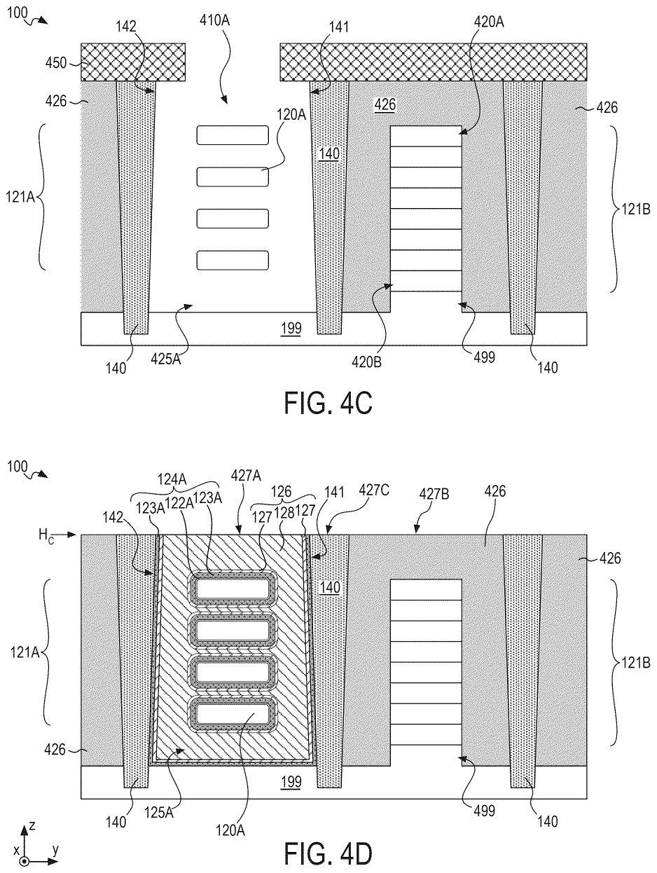

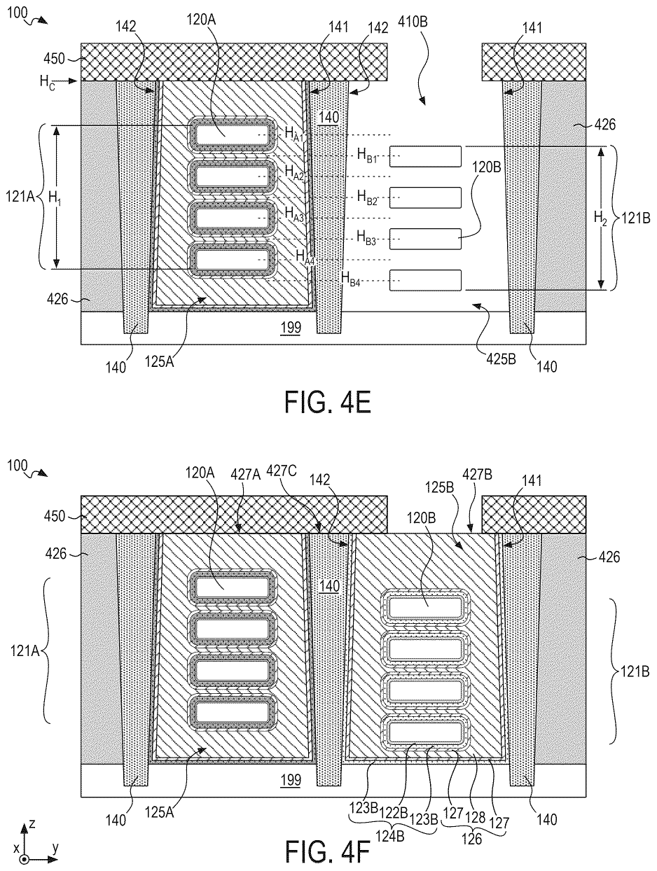

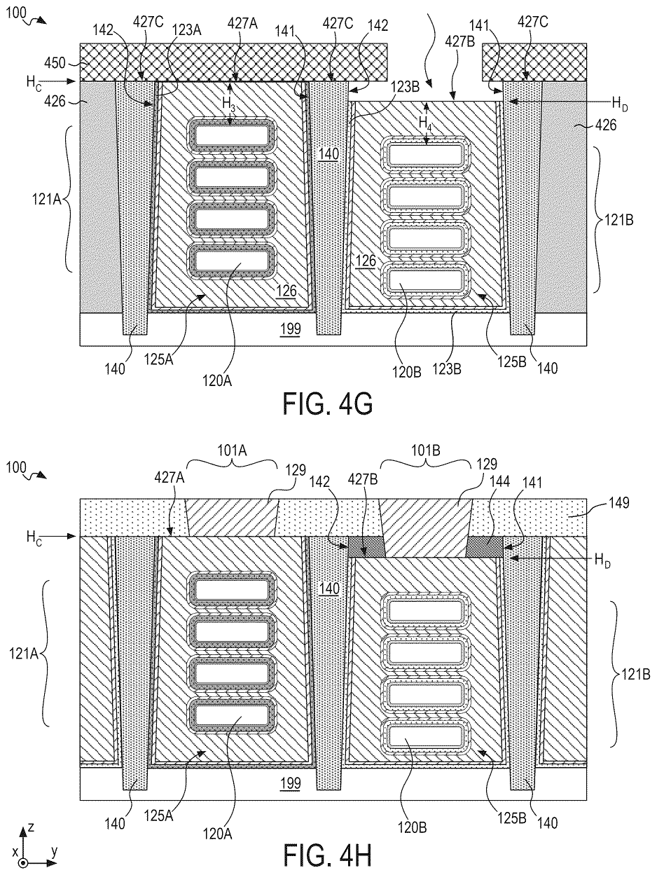

FIGS. 4A, 4B, 4C, 4D, 4E, 4F, 4G, and 4H illustrate profile views of an IC device 100 having gate structures of different heights and compositions over nanoribbons of different heights and compositions, at various stages of manufacture, in accordance with some embodiments. FIGS. 4A-4I show possible examples of intermediate structures during an embodiment of a practice of methods 300 of FIG. 3.

FIG. 4A illustrates IC device 100 having a dummy gate 426 over first and second stacks 121A, 121B of alternating first and second material layers 420A, 420B in substrate 199, in accordance with some embodiments, for example, prior to a performance of forming operation 310. Substrate 199 may include subfins 499 under one or both of stacks 121A, 121B. First and second material layers 420A, 420B may have thicknesses T_{A}, T_{B}, respectively. First and second stacks 121A, 121B may be separated by distance D.

In many embodiments, dummy gate 426 includes tungsten. In many embodiments, dummy gate 426 includes polycrystalline silicon. Dummy gate 426 is over, between, and to the sides of first and second stacks 121A, 121B.

In many embodiments, one of first and second material layers 420A, 420B are predominantly silicon, and the other of layers 420A, 420B are silicon germanium. In many embodiments, thicknesses T_{A}, T_{B} are approximately equal.

Returning to FIG. 3, methods 300 begin at operation 310 with forming a dielectric wall between first and second stacks of first and second material layers. The first and second stacks of first and second material layers may be first and second stacks of nanoribbons, of either the same or different compositions. In many embodiments, stacks of nanoribbons are formed from the stacks of material layers after the dielectric wall is formed between the stacks of material layers.

The first and second stacks of first and second material layers may be received on or in a substrate, such as an IC die or wafer, e.g., much as described of substrate 199 at FIG. 1A. The material layer stacks may be formed by any suitable means and of any suitable material(s). In many embodiments, the first and second material layers are deposited in a single stack of semiconducting material layers with mutual etch selectivities, and the stacks are cut up (e.g., etched) into many parallel, smaller stacks (e.g., fins) of first and second material layers. In some such embodiments, the smaller stacks or fins of first and second material layers are cut (e.g., in an orthogonal direction) to form more, smaller stacks or fins of first and second material layers aligned on a shared centerline or axis. In many embodiments, some of the parallel stacks are to be of alternating, complementary conductivity types (e.g., n- and p-types), and adjacent aligned (e.g., in-line) stacks or fins include channel layers that will share source or drain bodies grown in trenches between the adjacent fins. In many embodiments, first material layers are predominantly silicon (e.g., for n-type channels), and second material layers include silicon and germanium (e.g., for p-type channels). In many embodiments, first material layers are channel layers in the first stack and sacrificial layers in the second stack, and second material layers are channel layers in the second stack and sacrificial layers in the first stack.

The dielectric wall may be formed by any suitable means and of any suitable material(s). In many embodiments, forming the dielectric wall includes opening (e.g., etching) a cavity through a first dielectric material, for example, in a trench between pairs of first and second stacks of first and second layers (e.g., beyond ends of the first and second stacks of first and second layers). The etch may be an anisotropic etch (e.g., a plasma etch, in a line parallel to the layers and stacks). The etch may have a minimal width, for example, of 15 nm or less. The etch width may be less than a third of the height of the layer stacks. The etch (and subsequent dielectric wall) sidewalls may be nearly vertical, for example, separated by upper and lower widths differing only slightly (e.g., in a tapering profile that narrows slightly upwards or downwards). For example, the upper and lower widths may be within 1 nm. In many embodiments, the etch has a minimum width of 12 nm or less, which may enable sufficiently tight packing of material layer stacks and a consequent conservation of layout area. In some embodiments, the etch has a minimum width of 10 nm or less, which may enable superior packing of material layer stacks and conservation of layout area. Such small widths and tight laying out of material layer stacks may be enabled by a fine, high aspect ratio etch (e.g., through a dummy gate).

The first dielectric material may be in many, parallel trenches with pairs of stacks (e.g., many, many stacks of first and second layers) between each adjacent pair of parallel trenches. The etch may open many cavities through many parallel trenches, for example, extending substantially parallel to the first and second stacks of first and second material layers and beyond ends of the first and second stacks of first and second material layers (e.g., with the cavities longer than the material layers). A dummy gate may be over the first and second stacks (e.g., with the first dielectric material to all sides) and may extend in a direction substantially orthogonal to the first and second stacks of first and second material layers, and the cavity may be etched through the dummy gate with the first dielectric material, as well as through spacer dielectrics on sidewalls of the dummy gate, between the dummy gate and the trenches of the first dielectric material.

The dielectric wall may be formed by depositing a second dielectric material in the etched-open cavity (parallel with the material layers and stacks). The dielectric wall may be formed concurrently with many other dielectric walls, e.g., parallel dielectric walls on both sides of the many parallel material layers and stacks, all formed by concurrent etches and concurrent dielectric depositions. The concurrent wall formations may leave each material layer stack tightly bracketed or bookended by a pair of dielectric walls. Each dielectric wall may have opposing first and second sidewalls with a first portion of the dummy gate on the first sidewall and a second portion of the dummy gate on the second sidewall.

Excess deposited second dielectric material (e.g., over the dummy gates, now divided into multiple portions by the dielectric wall) may be removed by a chemical-mechanical planarization or polish (CMP). Such a CMP may planarize (or level to a single, shared height) upper surfaces of the substrate, including upper surfaces of the dielectric wall and the dummy gates to both sides of the dielectric wall. Each dielectric wall may have an upper surface between the first and second sidewalls, level with upper surfaces of the dummy gates to both sides of the dielectric wall.

The dielectric wall may include any suitable dielectric material, e.g., a material with etch selectivities with adjacent materials. For example, the deposited second dielectric material advantageously has good etch selectivities with the first dielectric material in the trenches at ends of the material layer stacks and with the sacrificial material of the dummy gate, both of which may be subsequently removed while the dielectric wall is retained. A spacer dielectric material may also be retained. Advantageously, the deposited (e.g., second) dielectric material is a low-k dielectric material. In many embodiments, depositing the second dielectric material deposits silicon and nitrogen, for example, with a CVD (chemical vapor deposition) or ALD (atomic layer deposition). The deposited, second dielectric material may be an isolation structure (e.g., dielectric wall) much as described of wall 140 at FIG. 1A.

Processing “tubs” may be formed by the dielectric wall(s), where each tub contains a material stack and is separated from a similar, adjacent tub by a dielectric wall. The tubs may be independent processing spaces, e.g., where a first tub (and material stack) can be processed separately from a second tub (and material stack), for example, isolated from each other by the dielectric wall. In many embodiments, forming the dielectric wall forms separate first and second tubs with the first stack of material layers (e.g., nanoribbons) in the first tub and the second stack of material layers (e.g., nanoribbons) in the second tub, for example, with each tub between a pair of adjacent dielectric walls. In some embodiments, both the first and second tubs include no third stack of nanoribbons (or other stack of material layers), e.g., the first stack of nanoribbons (and no other nanoribbon stack) is in the first tub and the second stack of nanoribbons (and no other nanoribbon stack) is in the second tub. Independent processing tubs (or groups of tubs) may be accessed by (e.g., lithographically) patterning a mask layer over the substrate with mask openings over the tubs to be processed. The dielectric walls (and the ample pitch between dielectric walls) enable separate processing of adjacent material stacks while allowing for even significant mask edge placement errors. Mask layers may be removed and re-patterned as necessary to access the same or different processing tubs (for example, in groups of tubs to undergo a certain processing operation).

As described, the dielectric wall(s) may be formed through a dummy gate over the stacks of first and second material layers. The stacks of first and second material layers may be between respective pairs of dielectric walls and in corresponding first and second tubs, e.g., that also contain corresponding first and second portions of the dummy gate. The dummy gate may be grown by any suitable means. In some embodiments, the stacks of first and second material layers are received as stacks of first and second nanoribbons, and the dummy gate is formed by depositing a metal (or other material) over and between nanoribbons in the first stack and between nanoribbons in the second stack. In some such embodiments, the metal or other material is deposited on protective (e.g., passivation) interface layers on and over the nanoribbons. In some embodiments, the deposited metal is tungsten. The dummy gate may be of any suitable material(s), for example, a material that may be etched through by a high-aspect ratio etch. In some embodiments, polycrystalline silicon is deposited as the dummy gate.

An interface layer may be formed (e.g., grown) over the nanoribbons, for example, before forming a dummy gate and depending on a dummy gate material. The interface layer may be between the nanoribbons and a subsequently deposited dummy gate. The interface layer may be a protective layer, e.g., that shields the nanoribbons from subsequent processing. For example, the interface layer may be a passivation layer (e.g., of a native oxide) that protects the nanoribbons from a subsequent deposition (and removal etch) of a dummy gate. Each nanoribbon may be covered by a thin interface (e.g., passivation) layer separate from the other nanoribbons and interface layers. In many embodiments, the interface layer includes oxygen. In many embodiments, the interface layer is on nanoribbons that include silicon, and the interface layer includes oxygen and silicon. The interface layer may be grown by any suitable means. In some embodiments, the interface layer is grown by exposure to oxygen, e.g., with an ozone treatment.

FIG. 4B shows IC device 100 having dielectric walls 140 between, and to the sides of, stacks 121A, 121B of material layers 420A, 420B and through the materials of dummy gates 426, in accordance with some embodiments, for example, following a performance of forming operation 310. A first upper surface 427A (of dummy gate 426 over first stack 121A of first material layers 420A), a second upper surface 427B (of dummy gate 426 over second stack 121B of second material layers 420B), and a third upper surface 427C (of dielectric wall 140) are all planarized to a same height H_{C}.

A width W₁ (or width W₂) of dielectric wall 140 separates sidewalls 141, 142. Dielectric wall 140 (e.g., sidewalls 141, 142) may be nearly vertical. In many embodiments, dielectric wall 140 has widths W₁, W₂ differing only slightly (e.g., in a tapering profile that narrows slightly upwards or downwards). For example, widths W₁, W₂ may be within 1 nm. Width W₁ is defined as the width of wall 140 at a top of wall 140. Width W₂ is defined as the width of wall 140 at a bottom of gates 426, e.g., where wall 140 meets substrate 199 at a bottom of gate 426. In many embodiments, dielectric wall 140 has a minimum width W₂ (or width W₁, etc.) of 12 nm or less, which may enable sufficiently tight packing of stacks 121A, 121B and a consequent conservation of layout area. In some embodiments, dielectric wall 140 has a minimum width W₂ (or width W₁, etc.) of 10 nm or less, which may enable superior packing of stacks 121A, 121B and conservation of layout area. Such (small widths W₁, W₂ and) tight laying out of stacks 121A, 121B may be enabled by a fine, high aspect ratio etch (e.g., through and between gate 426).

The tight packing of stacks 121 may also be characterized by a small distance D separating the first and second stacks 121A, 121B of material layers 420A, 420B. In many embodiments, distance D is less than three times a maximum width W₁ of wall 140. For example, if wall 140 is centered between stacks 121 and in distance D, wall 140 is less than a width W₁ from either stack.

Returning to FIG. 3, methods 300 continue at operation 320 with forming stacks of first and second nanoribbons. In many embodiments, the stacks of nanoribbons are formed (e.g., released) from the stacks of material layers with the dielectric wall between the stacks. In many embodiments, each stack of material layers is (in a tub) between a pair of dielectric walls, and the dielectric walls enable the independent processing of the stacks of material layers, including the release of nanoribbons from the material layer stacks. The dielectric wall(s) and independent processing of each stack of material layers in turn enables the releasing of nanoribbons in adjacent stacks, but with different heights, compositions, and/or thicknesses. For example, similar first and second stacks of first and second material layers on first and second sides of the dielectric wall may be independently processed to yield a first stack of nanoribbons from the first material layers on the first side of the dielectric wall and a second stack of nanoribbons from the second material layers on the second side of the dielectric wall.

In embodiments with the first material layers over the second material layers (e.g., within each pair of alternating first and second material layers), the resulting first nanoribbons in the first stack have first heights above second heights of the second nanoribbons in the second stack. In many embodiments, forming the stacks of first and second nanoribbons forms the first nanoribbons with a first stack or group of first heights and the second nanoribbons with a second stack or group of second heights interleaved with the first stack of first heights. For example, each of the first nanoribbons and the corresponding first heights are above (e.g., at a greater height than) each respective second nanoribbon and corresponding second height (e.g., with each second nanoribbon having a second height between a pair of first heights of the first nanoribbons above and below).

The stacks of first and second nanoribbons may be formed in similar fashions and by similar means, concurrently or sequentially (e.g., independently). Although the disclosure describes processing the first material layer stack and then describes processing the second material layer stack, the stacks may be processed together (or in the opposite order, or one after another in multiple sets of operations, etc.). Although the disclosure describes releasing and retaining (as nanoribbon channel layers) the first material layers in the first material layer stack and the second material layers in the second material layer stack (and removing as sacrificial layers the second material layers in the first material layer stack the first material layers in the second material layer stack), other configurations of material layers may be retained and further processed.

Forming a first stack of first nanoribbons may include opening a first (e.g., tub) cavity on a first side of the dielectric wall. In many embodiments, opening the first cavity exposes sidewalls of the first and second material layers in the first cavity, e.g., in the first material stack. The exposing the sidewalls of the first and second layers in the first stack may make the material layers available for further processing, while the first and second layers in the second stack may be kept masked (e.g., by a dummy gate material) on a second side of the dielectric wall.

The first cavity may be opened by any suitable means, for example, by patterning a rigid mask layer over the substrate with a mask opening over the first material layer stack and by isotropically (e.g., selectively) removing dummy gate material in a tub between a pair of dielectric walls. The exposing etch may expose other first material layer stacks to be concurrently processed (e.g., while second material layer stacks are left masked).

Forming the first stack of first nanoribbons may include releasing the first material layers in the first stack of material layers, for example, by selectively removing the second material layers in the first stack, between the first material layers. The channel material layers to be retained (e.g., first or second material layers in a given stack coupled with corresponding source and drain bodies) may be released by removing the sacrificial material layers adjacent (e.g., in the same stack, between) the channel material layers. The dielectric wall separating the first and second stacks may enable the separate release of channel material layers and removal of sacrificial material layers in the different stacks, including the retention of a first material and removal of a second material in a first stack and the retention of the second material and removal of the first material in a second stack.

The sacrificial material layers may be removed by any suitable means, for example, selective etches employing etch selectivities between the first and second material layers. Removing the different material layers on the different sides of the dielectric wall may result in adjacent first and second stacks of channel material layers (e.g., nanoribbons) with offset and interleaved heights.

With the first tub open, in some embodiments, further processing of the first stack may continue before processing (e.g., forming) the second stack. In some embodiments, first nanoribbons in the first stack are thinned (e.g., at operation 330) before the second nanoribbons are formed in the second stack. In some embodiments, a first gate structure is formed over the first nanoribbons in the first stack (e.g., at operation 340) before the second nanoribbons are formed in the second stack.

In some embodiments, the first stack is covered (and the first tub is filled) with a dummy gate or other sacrificial material, for example, to facilitate further processing of the second stack. The dummy gate material (e.g., a metal) may be deposited over and between the first nanoribbons. In some embodiments, an interface layer is formed (e.g., grown) on the first nanoribbons before depositing a dummy gate material in the first tub. The sacrificial material may protect the deposited layers and the nanoribbons. In some embodiments, the sacrificial material includes carbon (e.g., in a carbon hardmask). In some embodiments, the sacrificial material is cured with a nitrogen treatment.

A patterned hardmask layer over the substrate (e.g., covering the second stack, but with an opening over the first stack) may be removed for subsequent processing. In some embodiments, a hardmask layer over the gate tubs is removed by one or more isotropic etches and/or a CMP. Such an etch or CMP may planarize (e.g., recess and substantially level to a single, shared height) upper surfaces of the substrate, including upper surfaces of the dielectric wall and sacrificial material(s) to both sides of the dielectric wall.

Forming a second stack of second nanoribbons may include opening a second (e.g., tub) cavity on a second side of the dielectric wall. Opening the second cavity on the second side of the dielectric wall may be much like opening the first cavity on the first side of the dielectric wall, e.g., exposing and making available for further processing sidewalls of the first and second material layers in the second cavity, in the second material stack. The second cavity may be opened by any suitable means, e.g., by patterning a mask opening over the second material layer stack and by selectively removing a dummy gate material. The exposing etch may expose other second material layer stacks to be concurrently processed (e.g., while first material layer stacks are left masked).

Forming the second stack of second nanoribbons may include releasing the second material layers in the second stack of material layers, for example, by selectively removing the first material layers in the second stack, between the second material layers. The sacrificial (e.g., first) material layers may be removed by any suitable means, for example, selective etches employing etch selectivities between the first and second material layers (e.g., using a different etchant to remove the first material layers and retain the second material layers). Removing the different material layers on the different sides of the dielectric wall may result in adjacent first and second stacks of channel material layers (e.g., nanoribbons) with offset and interleaved heights.

FIG. 4C illustrates IC device 100 having stack 121A of first nanoribbons 120A in gate tub 425A, in accordance with some embodiments, for example, following a performance of forming operation 320. Nanoribbons 120A in stack 121A are released (e.g., without sacrificial material layers 420B on and between nanoribbons 120A). Stack 121A and gate tub 425A are accessible by patterned opening 410A in mask layer 450. No dummy gate 426 is present in tub 425A. Nanoribbons 120A and sidewalls 141, 142 (of dielectric walls 140) are exposed in gate tub 425A, e.g., available for processing.

Material layers 420A, 420B in stack 121B remain masked over by dummy gate 426 under mask layer 450 and between sidewalls 141, 142 of dielectric walls 140.

Returning to FIG. 3, methods 300 continue by thinning the first or second (e.g., channel) material layers at operation 330. The separate first and second (e.g., tub) cavities may enable the thinning of one or the other of the first or second material layers in only one of the first and second cavities, but layers in both the first and second cavities (and first and second stacks) may be thinned. The first or second (e.g., channel) material layers may be thinned by any suitable means, for example, by isotropically etching the layers. In some embodiments, the layer thinning may be done concurrently with removing the sacrificial material layers (e.g., by an over-etch). In some embodiments, the first nanoribbons are thinned to a first thickness less than a second thickness of the second nanoribbons. In some embodiments, the second nanoribbons are thinned to a first thickness less than a second thickness of the first nanoribbons.

Methods 300 continue by forming first and second gate structures over the stacks of first and second nanoribbons at operation 340. The first gate structure may include a first insulator layer and a first metal electrode, and the stack of first nanoribbons may extend through the first gate structure. The second gate structure may include a second insulator layer and a second metal electrode, and the stack of second nanoribbons may extend through the second gate structure. In many embodiments, forming the first gate structure includes depositing the first insulator layer on the first side or sidewall of the dielectric wall and over the stack of first nanoribbons. In many embodiments, forming the second gate structure includes depositing the second insulator layer on the second side or sidewall of the dielectric wall and over the stack of second nanoribbons.

The first and second gate structures may be formed in similar fashions and by similar means, concurrently or sequentially (e.g., independently). Although the disclosure describes processing the first gate structure and then describes processing the second gate structure, the stacks may be processed together (or in the opposite order, or one after another in multiple sets of operations, etc.). For example, after some gate-forming operation in the first (or second) gate tub, the first (or second) gate tub may be filled with sacrificial material for processing of the second (or first) gate tub, and then the second (or first) gate tub may be filled with sacrificial material for processing of the first (or second) gate tub, etc. Forming the first (or second) gate structure may include removing sacrificial material from the first (or second) gate tub, which may be much as described. Different sacrificial materials (and different operations removing the sacrificial materials) may be used at different operations within methods 300. Although the disclosure may describe certain gate configurations, other configurations (e.g., quantities or compositions of material layers) may be deployed.

Forming the first gate structure may include removing interface (e.g., passivation) layers from the first nanoribbons in the first nanoribbon stack. The interface layers may be removed by any suitable means. In many embodiments, the interface layers are removed by an etch of hydrofluoric acid (e.g., dilute hydrofluoric acid, DHF), for example, following an ozone treatment.

Forming the first gate structure may include forming a first dielectric stack on the first nanoribbons in the first nanoribbon stack. The first dielectric stack may be formed by any suitable means. In many embodiments, a first dielectric layer is grown on the first nanoribbons in the first nanoribbon stack. In many embodiments, a first insulator layer is deposited on the first dielectric layer grown on the first nanoribbons in the first nanoribbon stack. In some embodiments, a dipole dopant is deposited on the first dielectric layer on the first nanoribbons or on the first insulator layer on the first dielectric layer.

The first dielectric layer grown on the first nanoribbon stack may be similar to an interface layer, e.g., a native oxide or passivation layer grown from the nanoribbons. The first dielectric layer may be formed by any suitable means and of any suitable materials. The first dielectric layer on the first nanoribbon stack may be much as described of layer 122A at FIG. 1A, for example, having silicon and oxygen and a thickness T₁. Although the first dielectric layer may be similar to an interface layer (e.g., described at operation 310, etc.), the first dielectric layer may be grown in a more controlled fashion, for example, to a precise and controlled thickness. In some embodiments, the first dielectric layer is grown from the first nanoribbons, and a portion of a thickness of the first dielectric layer is consumed from a thickness of the first nanoribbon. A thicker first dielectric layer may correspond with a further-thinned first nanoribbon. In many embodiments, the first dielectric layer is grown on the first nanoribbon stack using an ozone treatment.

A first insulator layer may be deposited on the first dielectric layer on the first nanoribbons. In many embodiments, the deposited first insulator layer is a high-k dielectric layer. The first insulator layer may be much as described of layer 123A at FIG. 1A, for example, having oxygen and hafnium and/or zirconium and a thickness T₃. The first insulator layer may be formed by any suitable means and of any suitable materials. In many embodiments, the first insulator layer is deposited on the first dielectric layer on the first nanoribbons by an ALD, which may conformally deposit the first insulator layer in the first gate tub (and beyond, over the entire substrate). In many embodiments, the first insulator layer is deposited on the first side (e.g., first sidewall) of the dielectric wall. An ALD (or another suitable depositing means) may deposit the first insulator layer in an extremely controlled fashion and to a precise and controlled thickness.

A dipole dopant may be deposited on the first dielectric layer on the first nanoribbons or on the first insulator layer on the first dielectric layer. In some embodiments, an anneal (e.g., at an elevated temperature) is performed, for example, to drive the dipole dopant into either the first dielectric layer or the first insulator layer on the first dielectric layer. The dipole dopant may be in the first dielectric layer (e.g., at some depth, inclusive, between the first interface between the first nanoribbons and the first dielectric layer and a second interface between the first dielectric layer and the first insulator layer) or in or on the first insulator layer (e.g., at some depth, inclusive, between the second interface between the first dielectric layer and the first insulator layer and an outer surface of the first insulator layer). The anneal (e.g., to drive the dipole dopant into either of the layers) may be performed at any suitable point during methods 300, for example, before or after insulator layers are deposited on second nanoribbons in the second nanoribbon stack. A separate anneal (e.g., done on only the first insulator layers on first nanoribbons in the first nanoribbon stack) may drive the dipole dopant to a different depth in the first dielectric stack on the first nanoribbons than in dielectrics on the second nanoribbons.

Forming the first gate structure may include depositing a first metal layer on the first dielectric stack. The first metal layer may be a capping layer that protects the dielectric stack, for example, from further processing. In many embodiments, the first metal layer is a WFM layer. The first metal layer may be much as described of layer 127 in first gate structure 125A at FIG. 1A, for example, having a thickness T₅. The first metal layer may be formed by any suitable means and of any suitable materials, including non-metallic materials. In many embodiments, the first metal layer includes nitrogen (e.g., in a metal nitride). In some embodiments, the first metal layer includes titanium and nitrogen (e.g., in a nitride of titanium). In many embodiments, the first metal layer is deposited by a CVD or ALD.

Forming the first gate structure may include depositing a fill metal layer over the first metal layer on the first nanoribbon stack, e.g., completing a first gate electrode and the first gate structure such that the first stack of first nanoribbons extends through the first gate structure. The fill metal layer may be formed by any suitable means and of any suitable materials, including non-metallic materials. The fill metal layer and first gate electrode may be much as described of layer 128 and electrode 126, respectively, in transistor structure 101A at FIG. 1A.

The first cavity or gate tub may be filled with a sacrificial or dummy material, e.g., to cover the deposited gate structure layers of a partially formed gate structure during further processing. The sacrificial material may help retain the deposited layers adjacent the nanoribbons while allowing removal of the layers elsewhere, such as on a hardmask layer over the gate tubs. In some embodiments, the sacrificial material includes carbon (e.g., in a carbon hardmask). In some embodiments, the sacrificial material is cured with a nitrogen treatment. In some embodiments, the sacrificial material is or includes a metal. In some embodiments, the deposited layers on a hardmask layer over the gate tubs are removed by one or more isotropic etches and/or a CMP. Such an etch or CMP may planarize upper surfaces of the substrate, including upper surfaces of the dielectric wall and (e.g., sacrificial) material to either or both sides of the dielectric wall.

Forming the second gate structure may include removing interface (e.g., passivation) layers from the second nanoribbons in the second nanoribbon stack, which may be by any suitable means and may be similar to removing interface (e.g., passivation) layers from the first nanoribbons in the first nanoribbon stack, e.g., except on the second nanoribbon stack. In many embodiments, the interface layer is removed by a hydrofluoric acid etch.

Forming the second gate structure may include forming a second dielectric stack on the second nanoribbons in the second nanoribbon stack. Forming the second dielectric stack may be similar to the forming the first dielectric stack, e.g., except on the second nanoribbon stack. Notably, the forming the second dielectric stack on the second nanoribbon stack may be done with different materials, to different dimensions, etc., and the second dielectric stack may have different characteristics than the first dielectric stack. The second dielectric stack may be formed by any suitable means. In many embodiments, a second dielectric layer is grown on the second nanoribbons in the second nanoribbon stack. In many embodiments, a second insulator layer is deposited on the second dielectric layer on the second nanoribbons in the second nanoribbon stack. In some embodiments, a dipole dopant is deposited on the second dielectric layer on the second nanoribbons or on the second insulator layer on the second dielectric layer.

The second dielectric layer may be formed on the second nanoribbons by any suitable means and of any suitable materials. The second dielectric layer on the second nanoribbon stack may be much as described of layer 122B at FIG. 1A, for example, having silicon and oxygen and a thickness T₂. Notably, the second dielectric layer formed on the second nanoribbons may have a different thickness or material composition than the first dielectric layer formed on the first nanoribbons.

A second insulator layer may be deposited on the second dielectric layer on the second nanoribbons. In many embodiments, the second insulator layer is a high-k dielectric layer. The second insulator layer may be much as described of layer 123B at FIG. 1A, for example, having oxygen and hafnium and/or zirconium and a thickness T₄. The second insulator layer may be formed by any suitable means and of any suitable materials. Notably, the second insulator layer formed over the second nanoribbons may have a different thickness or material composition than the first insulator layer formed over the first nanoribbons.

A dipole dopant may be deposited on the second dielectric layer grown on the second nanoribbons or on the second insulator layer over the second nanoribbons. Notably, the dipole dopant deposited over the second nanoribbons may be of the same or a different material than the dopant deposited over the first nanoribbons and may be deposited at a different concentration or thickness, or driven to a different depth in the corresponding second dielectric stack than the dopant deposited over the first nanoribbons.

Forming the second gate structure may include depositing a second metal layer on the second dielectric stack. The forming the second metal layer may be similar to the forming the first metal layer, e.g., except on the second dielectric stack. Significantly, the forming the second metal layer on the second dielectric stack may be done with different materials, to different dimensions, etc., and the second gate structure may have different characteristics than the first gate structure. The second metal layer may be a capping layer that protects the second dielectric stack, for example, from further processing. In many embodiments, the second metal layer is a WFM layer. The second metal layer may be much as described of layer 127 in second gate structure 125B at FIG. 1A, for example, having a thickness T₆. The second metal layer may be formed by any suitable means and of any suitable materials, including non-metallic materials. In many embodiments, the second metal layer includes nitrogen. In some embodiments, the second metal layer includes titanium and nitrogen.

Forming the second gate structure may include depositing a fill metal layer over the second metal layer on the second nanoribbon stack, e.g., completing a second gate electrode and the second gate structure such that the second stack of second nanoribbons extends through the second gate structure. The fill metal layer may be formed by any suitable means and of any suitable materials, including non-metallic materials. The fill metal layer and second gate electrode may be much as described of layer 128 and electrode 126, respectively, in transistor structure 101B at FIG. 1A. The dielectric wall may be retained, and the first and second gate structures may be separated by the dielectric wall. The first and second gate electrodes (including first and second fill metals) may be formed of the same or different materials, e.g., having the same or different layers 127, 128. In some embodiments, fill metal layers in the first and second gate electrodes are formed concurrently, for example, deposited over different first and second WFM liner layers on first and second nanoribbons in open first and second gate tubs.

FIG. 4D shows IC device 100 having gate structure 125A over nanoribbons 120A (including gate insulator layer 123A on sidewalls 141, 142), in accordance with some embodiments, for example, following a performance of forming operation 340. First upper surface 427A (of structure 125A over first stack 121A of channel material layer nanoribbons 120A), second upper surface 427B (of dummy gate 426 over second stack 121B of second material layers 420B), and third upper surface 427C (of dielectric wall 140) are all planarized to height H_{C}.

First gate structure 125A includes first dielectric stack 124A on first nanoribbons 120A, and structure 125A includes a gate electrode 126, with dielectric stack 124A between electrode 126 and nanoribbons 120A. First dielectric stack 124A includes gate dielectric layers 122A on nanoribbons 120A and gate insulator layers 123A around nanoribbons 120A, on layers 122A. Gate electrode 126 includes metal layer 128 on liner layer 127, which is on layers 123A. Insulator layer 123A is on sidewalls 141, 142 of dielectric walls 140 bracketing structure 125A. In gate structure 125A, metal layer 127 is on insulator layer 123A on sidewalls 141, 142. Although not shown in FIG. 4D (or FIGS. 1A-1C, 2A-2C, etc.), in some embodiments, a subfin 499 may be under gate structure 125A (etc.), and lower surfaces of a gate structure 125 may be to either side of subfin 499, e.g., with subfin 499 forming a notch in structure 125 between the lower surfaces of a gate structure 125.

FIG. 4E illustrates IC device 100 having stack 121B of second nanoribbons 120B in gate tub 425B, in accordance with some embodiments, for example, following a performance of forming operations 320 and 340. Nanoribbons 120B in stack 121B are released (e.g., without sacrificial material layers 420A on and between nanoribbons 120B). Stack 121B and gate tub 425B are accessible by patterned opening 410B in mask layer 450. No dummy gate 426 is present in tub 425B. Nanoribbons 120B and sidewalls 141, 142 (of dielectric walls 140) are exposed in gate tub 425B, e.g., available for processing. Gate structure 125A is over nanoribbons 120A in stack 121A, covered by mask layer 450 and between dielectric walls 140.

In the exemplary embodiment of FIG. 4E, first nanoribbons 120A are predominantly silicon, and second nanoribbons 120B include silicon and germanium. First nanoribbons 120A are coupled with source and drain bodies (not shown) of predominantly silicon, and second nanoribbons 120B are coupled with source and drain bodies (not shown) including silicon and germanium. First nanoribbons 120A are at heights H_{A}, above corresponding heights H_{B} of second nanoribbons 120B. For example, first nanoribbons 120A are at heights H_{A1}, H_{A2}, H_{A3}, H_{A4} each above corresponding heights H_{B1}, H_{B2}, H_{B3}, H_{B4} of second nanoribbons 120B. First stack 121A of nanoribbons 120A has height H₁ equal to height H₂ of second stack 121B of second nanoribbons 120B.

FIG. 4F shows IC device 100 having gate structure 125B over nanoribbons 120B (including gate insulator layer 123B on sidewalls 141, 142), in accordance with some embodiments, for example, following a performance of forming operation 340. First upper surface 427A (of structure 125A over first stack 121A of channel material layer nanoribbons 120A), second upper surface 427B (of structure 125B over first stack 121B of channel material layer nanoribbons 120B), and third upper surface 427C (of dielectric wall 140) are all planarized at height H_{C}.

Second gate structure 125B includes second dielectric stack 124B on second nanoribbons 120B, and structure 125B includes a gate electrode 126, with dielectric stack 124B between electrode 126 and nanoribbons 120B. Second dielectric stack 124B includes gate dielectric layers 122B on nanoribbons 120B and gate insulator layers 123B around nanoribbons 120B, on layers 122B. Gate electrode 126 includes metal layer 128 on liner layer 127, which is on layers 123B. Gate electrode 126 (e.g., layers 127, 128) gate structure 125B may have a different composition than electrode 126 in gate structure 125A. Insulator layer 123B is on sidewalls 141, 142 of dielectric walls 140 bracketing structure 125B. In gate structure 125B, metal layer 127 is on insulator layer 123B on sidewalls 141, 142.

In the exemplary embodiment of FIG. 4F, layers 123A, 123B include hafnium, zirconium, and oxygen at different elemental ratios. Liner layers 127 of gate structures 125A, 125B are WFM layers 127 with different compositions, for example, to independently influence threshold voltages V_{T}. In some embodiments, at least some of the respective layers (e.g., layers 122, 123, 127) of structures 125A, 125B have different thicknesses.

Returning to FIG. 3, methods 300 continue with planarizing surfaces of the substrate to a first height at operation 350. For example, the planarizing the surfaces of the substrate to the first height may planarize or level a first upper surface over the first stack of first nanoribbons, a second upper surface over the second stack of second nanoribbons, and a third upper surface of the dielectric wall, all to a same height or level. In many embodiments, the planarizing the surfaces of the substrate planarizes a first upper surface of the first gate structure over the first nanoribbon stack, a second upper surface of the second gate structure over the second nanoribbon stack, and a third upper surface of the dielectric wall. The planarizing may level the first, second, and third surfaces all to a same first height over the first and second nanoribbons. In some embodiments, the planarizing levels upper surfaces of the dielectric wall and the first gate structure, for example, when the planarizing is performed before the second gate structure is formed. The planarizing may be by any suitable means. In many embodiments, the planarizing is by CMP.

Methods 300 continue at operation 360 by recessing a surface of the first or second gate structure down to a second height below the first height of the upper surface of the dielectric wall. In many embodiments, an upper surface of the second gate structure (e.g., the upper surface of the gate electrode (e.g., gate metal) of the second gate structure) is recessed to a second height below the first height of the upper surfaces of the dielectric wall and the first gate structure. In some such embodiments, the recessing of the upper surface of the second gate structure recesses the second dielectric layer of the second gate structure down to the second height below the first height. In other embodiments, the recessing of the upper surface of the second gate structure recesses the upper surface of the metal (e.g., gate electrode) of the second gate structure down to the second height below the first height, but retains the second dielectric layer on the sides or sidewalls of the dielectric sidewalls bracketing (e.g., to both sides of), and in contact with, the second gate structure.

One or both of the first and second gate structures may be recessed, for example, independently of the other gate structure, as enabled by the dielectric wall separating the gate structures. In some embodiments, the first and second gate structures are both recessed down to a second height below the first height of the upper surface of the dielectric wall. In some embodiments, the first gate structure (e.g., the respective gate electrode) is recessed down to a second height below the first height of the upper surface of the dielectric wall, and the second gate structure (e.g., the respective gate electrode) is recessed down to a third height below the second height of the first gate structure.

The recessing of the gate structure(s) may be down to any suitable height (e.g., depth) below the first height (e.g., of the upper surface of the dielectric wall). In many embodiments, the recessing the upper surface of the gate electrode of the second gate structure down to the second height below the first height recesses the gate electrode of the second gate structure to a thickness over an uppermost of the second nanoribbons equal to a thickness of the gate electrode (e.g., gate metal) of the first gate structure over an uppermost of the first nanoribbons. (The thicknesses of the gate metals or electrodes of the first and second gate structures may be considered equal if the thicknesses are within 1 nm.) For example, the recessing may zero out (or minimize) a difference between the first thickness (equal to a difference between a height of an upper surface of an uppermost of the first nanoribbons and an upper surface of the gate electrode of the first gate structure at the first height) and second thickness (equal to a difference between a height of an upper surface of an uppermost of the second nanoribbons and an upper surface of the gate electrode of the second gate structure at the second height). The recessing may reduce parasitic capacitances (e.g., between the second gate structure and adjacent structures, such as source or drain epi bodies and other gate electrodes), but the recessing may be constrained by minimum limits on the thicknesses of the respective gate electrodes over the corresponding nanoribbons.

The recessing of the gate structure(s) down to a second height below the first height may be by any suitable means. The first or second gate structure may be recessed by a selective, isotropic etch of the respective gate structure. In many embodiments, the recessing of the first or second gate structures includes depositing a mask layer over planarized upper surfaces of the dielectric wall and the first and second gate structures and forming an opening in the mask layer over the second gate structure. In many embodiments, the recessing of the first or second gate structures includes wet and/or dry etching the gate electrode of the respective first or second gate structure down to the second height. In some embodiments, the recessing of the first or second gate structure includes multiple etches. In some such embodiments, a first etch of the first or second gate structure recesses the gate electrode of the first or second gate structure, and a second etch of the first or second gate structure recesses the respective first or second gate insulator layer, e.g., removing the respective first or second gate insulator layer (e.g., above the second height) from the sidewalls of the dielectric walls bracketing the respective first or second gate structure.

An isolation layer of dielectric material may be deposited over one or both gate structure, e.g., to later be contacted through by a contact via.

FIG. 4G illustrates IC device 100 having gate structure 125B with upper surface 427B at height H_{D}, below height H_{C} of upper surfaces 427A, 427C of gate structure 125A and dielectric walls 140, in accordance with some embodiments, for example, following a performance of recessing operation 360.

Over nanoribbons 120A, dielectric layers 123A (e.g., on sidewalls 141, 142) and the metal(s) of gate electrode 126 in structure 125A extend up to height H_{C}. Over nanoribbons 120B, dielectric layers 123B (e.g., on sidewalls 141, 142) and the metal(s) of gate electrode 126 in structure 125B extend up to height H_{D}. Dielectric layer(s) 123B in structure 125B is not present on sidewalls 141, 142 above height H_{D}. Second upper surface 427B (of structure 125A over first stack 121B of channel material layer nanoribbons 120B) is at height H_{D}. First upper surface 427A (of structure 125A over first stack 121A of channel material layer nanoribbons 120A) and third upper surface 427C (of dielectric wall 140) are planarized at height H_{C}.

Height H_{C} is offset from an uppermost one of nanoribbons 120A by a vertical (span or distance or) height H₃, and height H_{D} is offset from an uppermost one of nanoribbons 120B by a vertical (span or distance or) height H₄. In the exemplary embodiment of FIG. 4G, vertical spans or heights H₃, H₄ are equal, e.g., with a thickness of a gate structure 125A over an uppermost nanoribbon 120A (between uppermost nanoribbon 120A and upper surface 427A) equal to a thickness of a gate structure 125B over an uppermost nanoribbon 120B (between uppermost nanoribbon 120B and upper surface 427B). In other embodiments, height H₃ is greater than height H₄, e.g., with a thickness of gate electrode 126 in gate structure 125A set by a CMP and a thickness of gate electrode 126 in gate structure 125B minimized by a recess etch. In some embodiments, height H₃ is less or shorter than height H₄, for example, with an upper surface 427B of gate electrode 126 in gate structure 125B recessed down from height H_{D} by a conservative etch.

FIG. 4H shows IC device 100 having dielectric layer 144 over gate structure 125B, between heights H_{C}, H_{D}, in accordance with some embodiments, for example, following a performance of recessing operation 360. An upper surface of dielectric layer 144 is at height H_{C}, and a lower surface of layer 144 is at height H_{D}. In the exemplary embodiment of FIG. 4H, dielectric layer 144 is between, and in contact with, sidewalls 141, 142.

Gate vias 129 contact gate structures 125A, 125B through dielectric layer 149 over transistor structures 101A, 101B. Via 129 over transistor structure 101B is also through dielectric layer 144. Gate vias 129 may (e.g., electrically) couple gate electrodes 126, for example, with an interconnect network (not shown) above transistor structures 101.

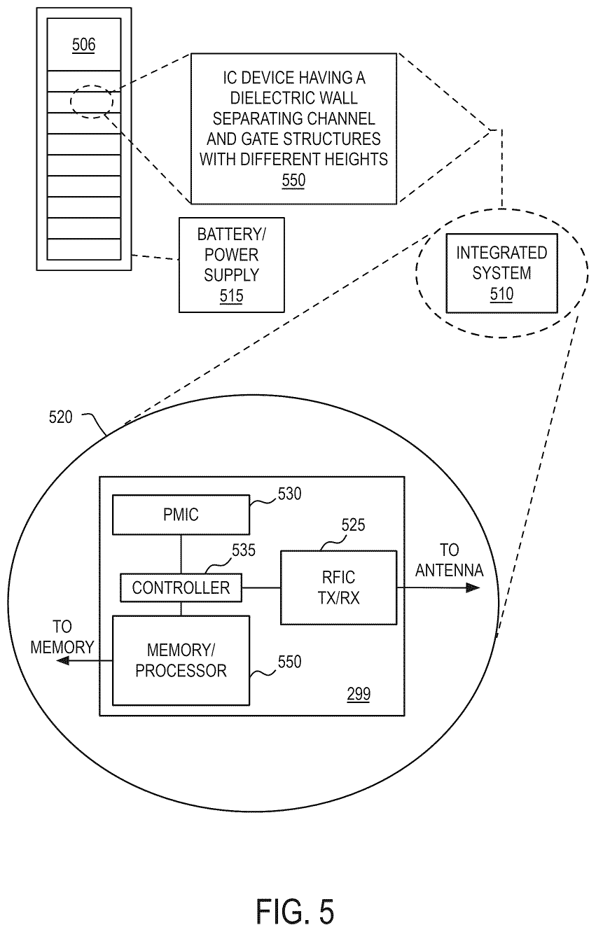

FIG. 5 illustrates a diagram of an example data server machine 506 employing an IC device having a dielectric wall separating channel and gate structures with different heights, in accordance with some embodiments. Server machine 506 may be any commercial server, for example, including any number of high-performance computing platforms disposed within a rack and networked together for electronic data processing, which in the exemplary embodiment includes one or more devices 550 having a dielectric wall separating channel and gate structures with different heights.

Also as shown, server machine 506 includes a battery and/or power supply 515 to provide power to devices 550, and to provide, in some embodiments, power delivery functions such as power regulation. Devices 550 may be deployed as part of a package-level integrated system 510. Integrated system 510 is further illustrated in the expanded view 520. In the exemplary embodiment, devices 550 (labeled “Memory/Processor”) includes at least one memory chip (e.g., random-access memory (RAM)), and/or at least one processor chip (e.g., a microprocessor, a multi-core microprocessor, or graphics processor, or the like) having the characteristics discussed herein. In an embodiment, device 550 is a microprocessor including a static RAM (SRAM) cache memory. As shown, device 550 may be an IC device having a dielectric wall separating channel and gate structures with different heights, as discussed herein. Device 550 may be further coupled to (e.g., communicatively coupled to) a board, an interposer, or other substrate or host component 299 along with, one or more of a power management IC (PMIC) 530, RF (wireless) IC (RFIC) 525 including a wideband RF (wireless) transmitter and/or receiver (TX/RX) (e.g., including a digital baseband and an analog front-end module further includes a power amplifier on a transmit path and a low noise amplifier on a receive path), and a controller 535 thereof. In some embodiments, RFIC 525, PMIC 530, controller 535, and device 550 include a dielectric wall separating channel and gate structures with different heights.

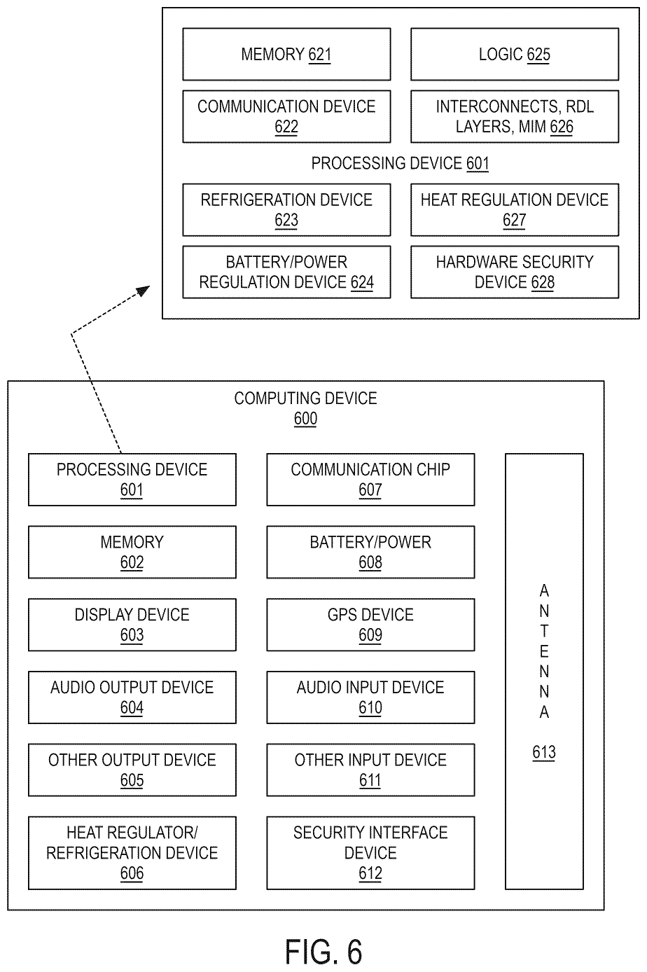

FIG. 6 is a block diagram of an example computing device 600, in accordance with some embodiments. For example, one or more components of computing device 600 may include any of the devices or structures discussed herein. A number of components are illustrated in FIG. 6 as being included in computing device 600, but any one or more of these components may be omitted or duplicated, as suitable for the application. In some embodiments, some or all of the components included in computing device 600 may be attached to one or more printed circuit boards (e.g., a motherboard). In some embodiments, various ones of these components may be fabricated onto a single system-on-a-chip (SoC) die. Additionally, in various embodiments, computing device 600 may not include one or more of the components illustrated in FIG. 6, but computing device 600 may include interface circuitry for coupling to the one or more components. For example, computing device 600 may not include a display device 603, but may include display device interface circuitry (e.g., a connector and driver circuitry) to which display device 603 may be coupled. In another set of examples, computing device 600 may not include an audio output device 604, other output device 605, global positioning system (GPS) device 609, audio input device 610, or other input device 611, but may include audio output device interface circuitry, other output device interface circuitry, GPS device interface circuitry, audio input device interface circuitry, audio input device interface circuitry, to which audio output device 604, other output device 605, GPS device 609, audio input device 610, or other input device 611 may be coupled.

Computing device 600 may include a processing device 601 (e.g., one or more processing devices). As used herein, the term “processing device” or “processor” indicates a device that processes electronic data from registers and/or memory to transform that electronic data into other electronic data that may be stored in registers and/or memory. Processing device 601 may include a memory 621, a communication device 622, a refrigeration device 623, a battery/power regulation device 624, logic 625, interconnects 626 (i.e., optionally including redistribution layers (RDL) or metal-insulator-metal (MIM) devices), a heat regulation device 627, and a hardware security device 628.

Processing device 601 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices.

Computing device 600 may include a memory 602, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, memory 602 includes memory that shares a die with processing device 601. This memory may be used as cache memory and may include embedded dynamic random-access memory (eDRAM) or spin transfer torque magnetic random-access memory (STT-MRAM).

Computing device 600 may include a heat regulation/refrigeration device 606. Heat regulation/refrigeration device 606 may maintain processing device 601 (and/or other components of computing device 600) at a predetermined low temperature during operation.

In some embodiments, computing device 600 may include a communication chip 607 (e.g., one or more communication chips). For example, the communication chip 607 may be configured for managing wireless communications for the transfer of data to and from computing device 600. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

Communication chip 607 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. Communication chip 607 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. Communication chip 607 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 607 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 607 may operate in accordance with other wireless protocols in other embodiments. Computing device 600 may include an antenna 613 to facilitate wireless communications and/or to receive other wireless communications (such as AM or FM radio transmissions).

In some embodiments, communication chip 607 may manage wired communications, such as electrical, optical, or any other suitable communication protocols (e.g., the Ethernet). As noted above, communication chip 607 may include multiple communication chips. For instance, a first communication chip 607 may be dedicated to shorter-range wireless communications such as Wi-Fi or Bluetooth, and a second communication chip 607 may be dedicated to longer-range wireless communications such as GPS, EDGE, GPRS, CDMA, WiMAX, LTE, EV-DO, or others. In some embodiments, a first communication chip 607 may be dedicated to wireless communications, and a second communication chip 607 may be dedicated to wired communications.

Computing device 600 may include battery/power circuitry 608. Battery/power circuitry 608 may include one or more energy storage devices (e.g., batteries or capacitors) and/or circuitry for coupling components of computing device 600 to an energy source separate from computing device 600 (e.g., AC line power).

Computing device 600 may include a display device 603 (or corresponding interface circuitry, as discussed above). Display device 603 may include any visual indicators, such as a heads-up display, a computer monitor, a projector, a touchscreen display, a liquid crystal display (LCD), a light-emitting diode display, or a flat panel display, for example.

Computing device 600 may include an audio output device 604 (or corresponding interface circuitry, as discussed above). Audio output device 604 may include any device that generates an audible indicator, such as speakers, headsets, or earbuds, for example.

Computing device 600 may include an audio input device 610 (or corresponding interface circuitry, as discussed above). Audio input device 610 may include any device that generates a signal representative of a sound, such as microphones, microphone arrays, or digital instruments (e.g., instruments having a musical instrument digital interface (MIDI) output).

Computing device 600 may include a GPS device 609 (or corresponding interface circuitry, as discussed above). GPS device 609 may be in communication with a satellite-based system and may receive a location of computing device 600, as known in the art.

Computing device 600 may include other output device 605 (or corresponding interface circuitry, as discussed above). Examples of the other output device 605 may include an audio codec, a video codec, a printer, a wired or wireless transmitter for providing information to other devices, or an additional storage device.

Computing device 600 may include other input device 611 (or corresponding interface circuitry, as discussed above). Examples of the other input device 611 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 600 may include a security interface device 612. Security interface device 612 may include any device that provides security measures for computing device 600 such as intrusion detection, biometric validation, security encode or decode, access list management, malware detection, or spyware detection.

Computing device 600, or a subset of its components, may have any appropriate form factor, such as a hand-held or mobile computing device (e.g., a cell phone, a smart phone, a mobile internet device, a music player, a tablet computer, a laptop computer, a netbook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

The subject matter of the present description is not necessarily limited to specific applications illustrated in FIGS. 1A-6. The subject matter may be applied to other deposition applications, as well as any appropriate manufacturing application, as will be understood to those skilled in the art.

The following examples pertain to further embodiments, and specifics in the examples may be used anywhere in one or more embodiments.

In one or more first embodiments, an apparatus includes a stack of first nanoribbons extending through a first gate structure in a first transistor structure, the first gate structure including a first metal and a first insulator layer, the first metal extending up to a first height, a stack of second nanoribbons extending through a second gate structure in a second transistor structure, the second gate structure including a second metal and a second insulator layer, the second metal extending up to a second height, the first height greater than the second height, and a dielectric structure between the stacks of first and second nanoribbons, the dielectric structure including opposing first and second sidewalls, wherein the first insulator layer is on the first sidewall, and the second insulator layer is on the second sidewall.

In one or more second embodiments, further to the first embodiments, the stack of first nanoribbons includes a plurality of third heights, a first vertical pitch between adjacent third heights of individual ones of the first nanoribbons, the stack of second nanoribbons includes a plurality of fourth heights, a second vertical pitch between adjacent fourth heights of individual ones of the second nanoribbons, and each adjacent pair of the first nanoribbons includes upper and lower first nanoribbons, the upper first nanoribbon with a corresponding third height above a corresponding fourth height of an adjacent second nanoribbon and the lower first nanoribbon with a corresponding third height below the corresponding fourth height of the adjacent second nanoribbon.

In one or more third embodiments, further to the first or second embodiments, a first vertical distance between an uppermost one of the first nanoribbons and an uppermost surface of the first gate structure is approximately equal to a second vertical distance between an uppermost one of the second nanoribbons and an uppermost surface of the second gate structure.

In one or more fourth embodiments, further to the first through third embodiments, an upper surface of the dielectric structure is at a third height above the first and second heights.

In one or more fifth embodiments, further to the first through fourth embodiments, the first nanoribbons have a first composition different than a second composition of the second nanoribbons.

In one or more sixth embodiments, further to the first through fifth embodiments, the first nanoribbons have a first thickness greater or less than a second thickness of the second nanoribbons.

In one or more seventh embodiments, further to the first through sixth embodiments, the first insulator layer is on the first sidewall below the first height, the second insulator layer is on the second sidewall below the second height, and the second insulator layer is not present on the second sidewall above the second height.

In one or more eighth embodiments, further to the first through seventh embodiments, the first insulator layer is on or around individual ones of the first nanoribbons, and the second insulator layer is on or around individual ones of the second nanoribbons.

In one or more ninth embodiments, further to the first through eighth embodiments, the first insulator layer has a first composition different than a second composition of the second insulator layer, or the first insulator layer has a first thickness greater or less than a second thickness of the second insulator layer.

In one or more tenth embodiments, further to the first through ninth embodiments, the first and second transistor structures are in a first substrate, the first substrate is coupled with a second substrate, and the first and second transistor structures are coupled with a power supply by the second substrate.

In one or more eleventh embodiments, an apparatus includes a stack of first nanoribbons extending through a first gate structure in a first transistor structure, the first gate structure including a first insulator layer, a stack of second nanoribbons extending through a second gate structure in a second transistor structure, the second gate structure including a metal and a second insulator layer, the second insulator layer between the metal and the second nanoribbons, and a dielectric wall between the first and second gate structures, the dielectric wall including opposing first and second sides, wherein the first insulator layer is on the first side up to a first height, the first insulator layer is around an individual one of the first nanoribbons, the second insulator layer is on the second side and around an individual one of the second nanoribbons, and the metal extends up to a second height below the first height.

In one or more twelfth embodiments, further to the eleventh embodiments, a third height of an uppermost one of the first nanoribbons is greater than a fourth height of an uppermost one of the second nanoribbons.

In one or more thirteenth embodiments, further to the eleventh or twelfth embodiments, a first vertical distance between the uppermost one of the first nanoribbons and the first height is approximately equal to a second vertical distance between the uppermost one of the second nanoribbons and the second height.

In one or more fourteenth embodiments, further to the eleventh through thirteenth embodiments, the first and second transistor structures are in a first substrate, the first substrate is coupled with a second substrate, and the first and second transistor structures are coupled with a power supply by the second substrate.

In one or more fifteenth embodiments, a method includes planarizing first, second, and third surfaces of a substrate to a first height, wherein the first surface is over a stack of first nanoribbons, the second surface is over a stack of second nanoribbons, and a dielectric wall includes the third surface between the first and second surfaces, and recessing a first metal of a first gate structure to a second height below the first height, the dielectric wall including opposing first and second sidewalls between the first gate structure and a second gate structure, the first gate structure including a first insulator layer and the first metal, the first insulator layer on the first sidewall, the stack of first nanoribbons extending through the first gate structure, the second gate structure including a second insulator layer and a second metal, the second insulator layer on the second sidewall, the stack of second nanoribbons extending through the second gate structure.

In one or more sixteenth embodiments, further to the fifteenth embodiments, the recessing the first metal to the second height below the first height recesses the first insulator layer down to the second height.

In one or more seventeenth embodiments, further to the fifteenth or sixteenth embodiments, the recessing the first metal to the second height below the first height recesses the first metal to a first thickness over an uppermost of the first nanoribbons equal to a second thickness of the second metal over an uppermost of the second nanoribbons.

In one or more eighteenth embodiments, further to the fifteenth through seventeenth embodiments, the recessing the first metal of the first gate structure to the second height below the first height includes depositing a mask layer over the planarized first, second, and third surfaces of the substrate, forming an opening in the mask layer over the stack of first nanoribbons, and wet etching the first metal to the second height.

In one or more nineteenth embodiments, further to the fifteenth through eighteenth embodiments, the method also includes forming the first and second gate structures, wherein forming the first gate structure includes depositing the first insulator layer on the first sidewall of the dielectric wall and over the stack of first nanoribbons, and forming the second gate structure includes depositing the second insulator layer on the second sidewall of the dielectric wall and over the stack of second nanoribbons.

In one or more twentieth embodiments, further to the fifteenth through nineteenth embodiments, the method also includes forming the stacks of first and second nanoribbons, wherein the stack of first nanoribbons includes a plurality of third heights, the stack of second nanoribbons includes a plurality of fourth heights, and the third heights of the first nanoribbons are interleaved with the fourth heights of the second nanoribbons.

The disclosure can be practiced with modification and alteration, and the scope of the appended claims is not limited to the embodiments so described. For example, the above embodiments may include specific combinations of features. However, the above embodiments are not limiting in this regard and, in various implementations, the above embodiments may include the undertaking only a subset of such features, undertaking a different order of such features, undertaking a different combination of such features, and/or undertaking additional features than those features explicitly listed. The scope of the patent rights should, therefore, be determined with reference to the appended claims, along with the full scope of equivalents to which such claims are entitled.

We claim:

1. An apparatus, comprising:
a stack of first nanoribbons extending through a first gate structure in a first transistor structure, the first gate structure comprising a first metal and a first insulator layer, the first metal extending up to a first height;
a stack of second nanoribbons extending through a second gate structure in a second transistor structure, the second gate structure comprising a second metal and a second insulator layer, the second metal extending up to a second height, the first height greater than the second height; and
a dielectric structure between the stacks of first and second nanoribbons, the dielectric structure comprising opposing first and second sidewalls, wherein the first insulator layer is on the first sidewall, and the second insulator layer is on the second sidewall.

2. The apparatus of claim 1, wherein:
the stack of first nanoribbons comprises a plurality of third heights, a first vertical pitch between adjacent third heights of individual ones of the first nanoribbons;
the stack of second nanoribbons comprises a plurality of fourth heights, a second vertical pitch between adjacent fourth heights of individual ones of the second nanoribbons; and
each adjacent pair of the first nanoribbons includes upper and lower first nanoribbons, the upper first nanoribbon with a corresponding third height above a corresponding fourth height of an adjacent second nanoribbon and the lower first nanoribbon with a corresponding third height below the corresponding fourth height of the adjacent second nanoribbon.

3. The apparatus of claim 2, wherein a first vertical distance between an uppermost one of the first nanoribbons and an uppermost surface of the first gate structure is approximately equal to a second vertical distance between an uppermost one of the second nanoribbons and an uppermost surface of the second gate structure.

4. The apparatus of claim 1, wherein an upper surface of the dielectric structure is at a third height above the first and second heights.

5. The apparatus of claim 1, wherein the first nanoribbons have a first composition different than a second composition of the second nanoribbons.

6. The apparatus of claim 1, wherein the first nanoribbons have a first thickness greater or less than a second thickness of the second nanoribbons.

7. The apparatus of claim 1, wherein:
the first insulator layer is on the first sidewall below the first height;
the second insulator layer is on the second sidewall below the second height; and
the second insulator layer is not present on the second sidewall above the second height.

8. The apparatus of claim 1, wherein the first insulator layer is on or around individual ones of the first nanoribbons, and the second insulator layer is on or around individual ones of the second nanoribbons.

9. The apparatus of claim 1, wherein:
the first insulator layer has a first composition different than a second composition of the second insulator layer; or
the first insulator layer has a first thickness greater or less than a second thickness of the second insulator layer.

10. The apparatus of claim 1, wherein:
the first and second transistor structures are in a first substrate;
the first substrate is coupled with a second substrate; and
the first and second transistor structures are coupled with a power supply by the second substrate.

11. An apparatus, comprising:
a stack of first nanoribbons extending through a first gate structure in a first transistor structure, the first gate structure comprising a first insulator layer;
a stack of second nanoribbons extending through a second gate structure in a second transistor structure, the second gate structure comprising a metal and a second insulator layer, the second insulator layer between the metal and the second nanoribbons; and
a dielectric wall between the first and second gate structures, the dielectric wall comprising opposing first and second sides, wherein the first insulator layer is on the first side up to a first height, the first insulator layer is around an individual one of the first nanoribbons, the second insulator layer is on the second side and around an individual one of the second nanoribbons, and the metal extends up to a second height below the first height.

12. The apparatus of claim 11, wherein a third height of an uppermost one of the first nanoribbons is greater than a fourth height of an uppermost one of the second nanoribbons.

13. The apparatus of claim 12, wherein a first vertical distance between the uppermost one of the first nanoribbons and the first height is approximately equal to a second vertical distance between the uppermost one of the second nanoribbons and the second height.

14. The apparatus of claim 11, wherein:
the first and second transistor structures are in a first substrate;
the first substrate is coupled with a second substrate; and
the first and second transistor structures are coupled with a power supply by the second substrate.

15. A method, comprising:
planarizing first, second, and third surfaces of a substrate to a first height, wherein the first surface is over a stack of first nanoribbons, the second surface is over a stack of second nanoribbons, and a dielectric wall comprises the third surface between the first and second surfaces; and
recessing a first metal of a first gate structure to a second height below the first height, the dielectric wall comprising opposing first and second sidewalls between the first gate structure and a second gate structure, the first gate structure comprising a first insulator layer and the first metal, the first insulator layer on the first sidewall, the stack of first nanoribbons extending through the first gate structure, the second gate structure comprising a second insulator layer and a second metal, the second insulator layer on the second sidewall, the stack of second nanoribbons extending through the second gate structure.

16. The method of claim 15, wherein the recessing the first metal to the second height below the first height recesses the first insulator layer down to the second height.

17. The method of claim 15, wherein the recessing the first metal to the second height below the first height recesses the first metal to a first thickness over an uppermost of the first nanoribbons equal to a second thickness of the second metal over an uppermost of the second nanoribbons.

18. The method of claim 15, wherein the recessing the first metal of the first gate structure to the second height below the first height comprises:
depositing a mask layer over the planarized first, second, and third surfaces of the substrate;
forming an opening in the mask layer over the stack of first nanoribbons; and
wet etching the first metal to the second height.

19. The method of claim 15, further comprising forming the first and second gate structures, wherein forming the first gate structure comprises depositing the first insulator layer on the first sidewall of the dielectric wall and over the stack of first nanoribbons, and forming the second gate structure comprises depositing the second insulator layer on the second sidewall of the dielectric wall and over the stack of second nanoribbons.

20. The method of claim 15, further comprising forming the stacks of first and second nanoribbons, wherein:
the stack of first nanoribbons comprises a plurality of third heights;
the stack of second nanoribbons comprises a plurality of fourth heights; and
the third heights of the first nanoribbons are interleaved with the fourth heights of the second nanoribbons.
